(19) United States
(12) Patent Application Publication
(10) Pub. No.: US 2026/0059755 A1
(43) Pub. Date: Feb. 26, 2026

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Sangdon Lee, Suwon-si (KR); Younghwan Son, Suwon-si (KR); Shinhwan Kang, Suwon-si (KR); Sukkang Sung, Suwon-si (KR)

(21) Appl. No.: 19/173,336

(22) Filed: Apr. 8, 2025

(30) Foreign Application Priority Data
Aug. 23, 2024 (KR) 10-2024-0113539

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor device and an electronic system are provided. The semiconductor device includes a substrate, a first sub-stack including first interlayer insulating layers and first conductive patterns alternately stacked on the substrate, a second sub-stack including second interlayer insulating layers and second conductive patterns alternately stacked on the first sub-stack, an intermediate insulating layer between the first and second sub-stacks, a vertical channel penetrating the first and second sub-stacks and the intermediate insulating layer, a first data storage pattern penetrating the first sub-stack and surrounding a first vertical portion of the vertical channel, and a second data storage pattern penetrating the second sub-stack and surrounding a second vertical portion of the vertical channel, wherein the vertical channel includes an impurity region adjacent to the intermediate insulating layer, the impurity region doped with impurities of a first conductive type.

### CROSS-REFERENCE TO RELATED APPLICATIONS

This U.S. non-provisional patent application claims priority under 35 U.S.C. § 119 to Korean Patent Application No.10-2024-0113539 filed on Aug. 23, 2024, in the Korean Intellectual Property Office, the entire contents of which are hereby incorporated by reference.

### BACKGROUND

Implementations relate to a semiconductor memory device and an electronic system including the same.

Semiconductor devices capable of storing a large amount of data in electronic systems requiring data storage may be desirable. Therefore, methods for increasing capacity of data storage of semiconductor devices have been researched. For example, to increase capacity of data storage of semiconductor devices, a semiconductor device including memory cells arranged three-dimensionally instead of memory cells arranged two-dimensionally has been proposed.

### SUMMARY

Some implementations provide a semiconductor device with improved reliability and integration.

Some implementations is to provide an electronic system including a semiconductor device.

The problem to be solved is not limited to the problems mentioned above, and other problems not mentioned may be clearly understood by those skilled in the art from the description below.

According to some implementations, a semiconductor device may include a substrate, a first sub-stack including first interlayer insulating layers and first conductive patterns alternately stacked on the substrate, a second sub-stack including second interlayer insulating layers and second conductive patterns alternately stacked on the first sub-stack, an intermediate insulating layer between the first and second sub-stacks, a vertical channel penetrating the first and second sub-stacks and the intermediate insulating layer, a first data storage pattern penetrating the first sub-stack and surrounding a first vertical portion of the vertical channel, and a second data storage pattern penetrating the second sub-stack and surrounding a second vertical portion of the vertical channel, wherein the vertical channel includes an impurity region adjacent to the intermediate insulating layer, the impurity region doped with impurities of a first conductive type.

According to some implementations, a semiconductor device may include a common source line on a substrate, a bit line on the common source line, a plurality of sub-stacks vertically stacked between the common source line and the bit line, a vertical channel vertically penetrating the plurality of sub-stacks, and a semiconductor device including data storage patterns surrounding the vertical channel and vertically penetrating each of the sub-stacks, wherein the vertical channel includes an impurity region doped with impurities of a first conductivity type between the sub-stacks, each of the sub-stacks includes interlayer insulating layers and conductive patterns that are vertically alternately stacked, and the conductive patterns comprise a first erase control line provided at an uppermost pattern thereof and a second erase control line provided at a lowermost pattern thereof, in each of the sub-stacks.

According to some implementations, an electronic system may include a semiconductor device including a substrate, a first sub-stack including first insulating layers and first conductive patterns alternately stacked on the substrate, a second sub-stack including second insulating layers and second conductive patterns alternately stacked on the first sub-stack, a vertical channel penetrating the first and second sub-stacks, a first data storage pattern penetrating the first sub-stack and surrounding a first vertical portion of the vertical channel, a second data storage pattern penetrating the second sub-stack and surrounding a second vertical portion of the vertical channel, and an input/output pad electrically connected to peripheral circuits and a controller electrically connected to the semiconductor device through the input/output pad and controlling the semiconductor device, wherein the vertical channel includes an impurity region doped with impurities of a first conductive type between the first sub-stack and the second sub-stack.

Specific details of other implementations are included in the detailed description and drawings.

### BRIEF DESCRIPTION OF THE DRAWINGS

Example implementations will be more clearly understood from the following brief description taken in conjunction with the accompanying drawings. The accompanying drawings represent non-limiting, example implementations as described herein.

FIG. 1 is a schematic diagram illustrating an electronic system including a semiconductor device according to some implementations.

FIG. 2 is a perspective diagram schematically illustrating an electronic system including a semiconductor device according to some implementations.

FIGS. 3 and 4 are cross-sectional views schematically illustrating semiconductor packages according to implementations.

FIG. 5 is a circuit diagram illustrating a memory block of a semiconductor device according to some implementations.

FIG. 6 is a cross-sectional view illustrating a portion of a semiconductor device according to some implementations.

FIGS. 7 and 8 are enlarged views of portion ‘P1’ of FIG. 6.

FIGS. 9 to 16 are cross-sectional views for explaining a method for manufacturing a semiconductor device according to some implementations.

FIGS. 17A to 17E are drawings illustrating in detail a method for manufacturing a semiconductor device according to implementations, and are enlarged views of portions ‘P1’ of FIGS. 13, 14, and 15.

FIGS. 18A to 18E are drawings illustrating in detail a method for manufacturing a semiconductor device according to implementations, and are enlarged views of portions ‘P1’ of FIGS. 13, 14, and 15.

FIGS. 19A to 19E are drawings illustrating in detail a method for manufacturing a semiconductor device according to implementations, and are enlarged views of portions ‘P1’ of FIGS. 13, 14, and 15.

FIG. 20 is a drawing for explaining an erase operation of a semiconductor device according to some implementations.

### DETAILED DESCRIPTION

Hereinafter, a semiconductor device and an electronic system including the same according to implementations will be described in detail with reference to the drawings.

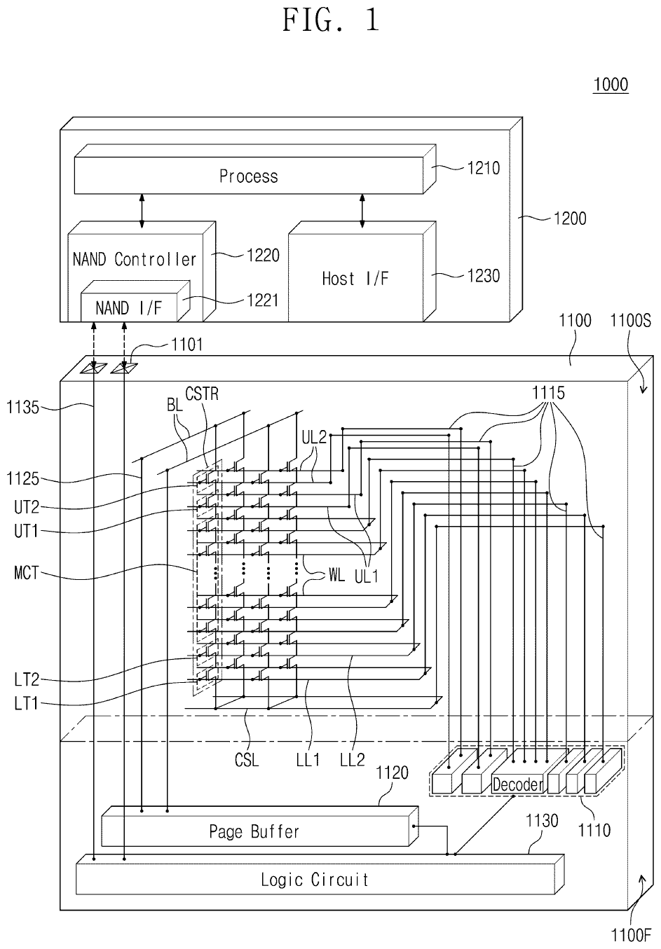

FIG. 1 is a schematic diagram illustrating an electronic system including a semiconductor device according to some implementations.

Referring to FIG. 1, an electronic system 1000 according to some implementations may include a semiconductor device 1100 and a controller 1200, which are electrically connected to each other. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In some implementations, the first structure 1100F may be disposed beside the second structure 1100S.

The first structure 1100F may be a peripheral circuit structure, which includes a decoder circuit 1110, a page buffer 1120, and a logic circuit 1130. The second structure 1100S may include a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to implementations.

In some implementations, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cell transistors MCT, and the gate upper lines UL1 and UL2 may be respectively used as gate electrodes of the upper transistors UT1 and UT2.

The memory cells MCT of each memory cell string CSTR may be controlled by the back gate line.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F into the second structure 1100S.

In the first structure 1100F, the decoder circuit 1110 and the page buffer 1120 may perform a control operation on at least one of the memory cell transistors MCT by a selection memory cell transistor. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is provided in the first structure 1100F and is extended into the second structure 1100S.

The first structure 1100F may include a voltage generator. The voltage generator may generate a program voltage, a read voltage, a pass voltage, a verification voltage, and so forth, which are needed to operate the memory cell strings CSTR. Here, the program voltage may be a relatively high voltage (e.g., 20V to 40V), compared with the read voltage, the pass voltage, and the verification voltage.

In some implementations, the first structure 1100F may include high-voltage transistors and low-voltage transistors. The decoder circuit 1110 may include pass transistors which are connected to the word lines WL of the memory cell strings CSTR. The pass transistors may include high-voltage transistors which may withstand or handle a high voltage applied to the word lines WL during a programming operation. The page buffer 1120 may include high-voltage transistors which may withstand or handle the high voltage.

The controller 1200 may include a processor 1210, a NAND controller 1220, and a host interface 1230. In some implementations, the electronic system 1000 may include a plurality of semiconductor devices 1100, and in this case, the controller 1200 may control the semiconductor devices 1100.

The processor 1210 may control overall operations the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands to control the semiconductor device 1100, data to be written in or read from the memory cell transistors MCT of the semiconductor device 1100, and so forth. The host interface 1230 may allow communication between the electronic system 1000 and an external host. When a control command is received from an external host through the host interface 1230, the processor 1210 may control the semiconductor device 1100 in response to the control command.

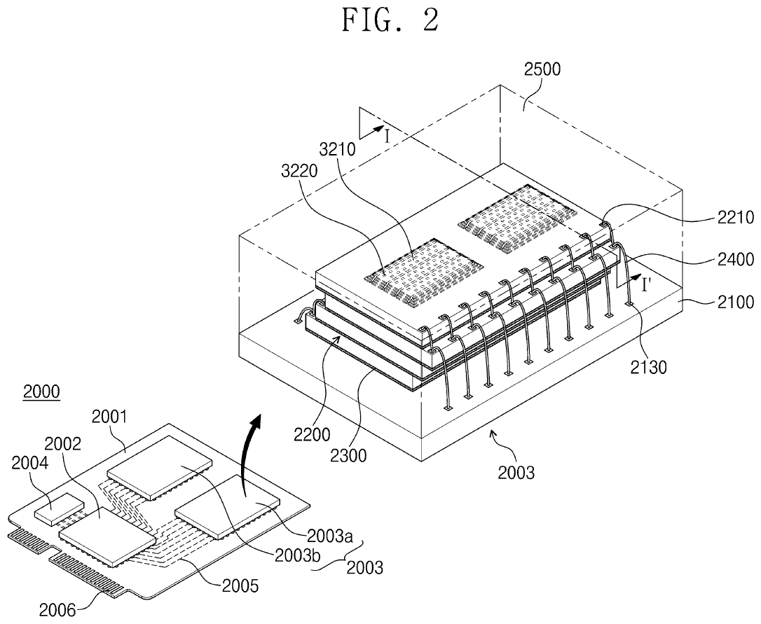

FIG. 2 is a perspective view illustrating an electronic system including a semiconductor device according to some implementations.

Referring to FIG. 2, an electronic system 2000 according to some implementations may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In some implementations, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In some implementations, the electronic system 2000 may be driven by a power, which is supplied from the external host through the connector 2006. The electronic system 2000 may further include a Power Management Integrated Circuit (PMIC) distributing power, which is supplied from the external host, to the controller 2002 and the semiconductor package 2003.

The controller 2002 may control a writing or reading operation on the semiconductor package 2003, thereby improving an operation speed of the electronic system 2000.

The DRAM 2004 may be a buffer memory, which relieves technical difficulties caused by a difference in speed between the semiconductor package 2003, which serves as a data storage device, and an external host. In some implementations, the DRAM 2004 in the electronic system 2000 may serve as a cache memory and may provide a storage space to temporarily store data during a control operation on the semiconductor package 2003. When the electronic system 2000 includes the DRAM 2004, the controller 2002 may further include a DRAM controller to control the DRAM 2004, in addition to a NAND controller to controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include an input/output pad 2210. The input/output pad 2210 may correspond to the input/output pad 1101 of FIG. 1. Each of the semiconductor chips 2200 may include gate stacks 3210 and vertical structures 3220. Each of the semiconductor chips 2200 may include a semiconductor device, which will be described below, according to some implementations.

In some implementations, the connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. In other implementations, the semiconductor chips 2200 in each of the first and second semiconductor packages 2003a and 2003b may be electrically connected to each other by a connection structure including through silicon vias (TSV), not by the connection structure 2400 provided in the form of bonding wires.

In some implementations, the controller 2002 and the semiconductor chips 2200 may be included in a single package. In some implementations, the controller 2002 and the semiconductor chips 2200 may be mounted on a separate interposer substrate, which is prepared regardless of the main substrate 2001, and may be connected to each other through interconnection lines, which are provided in the interposer substrate.

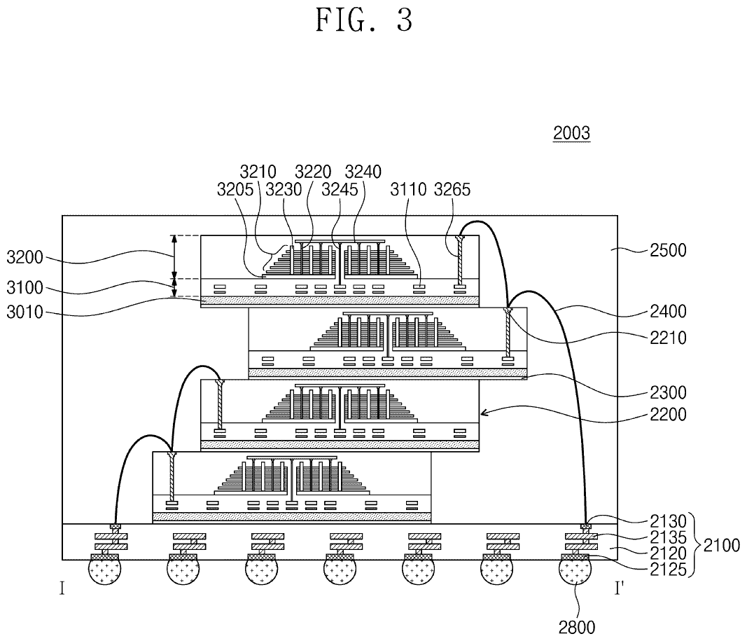

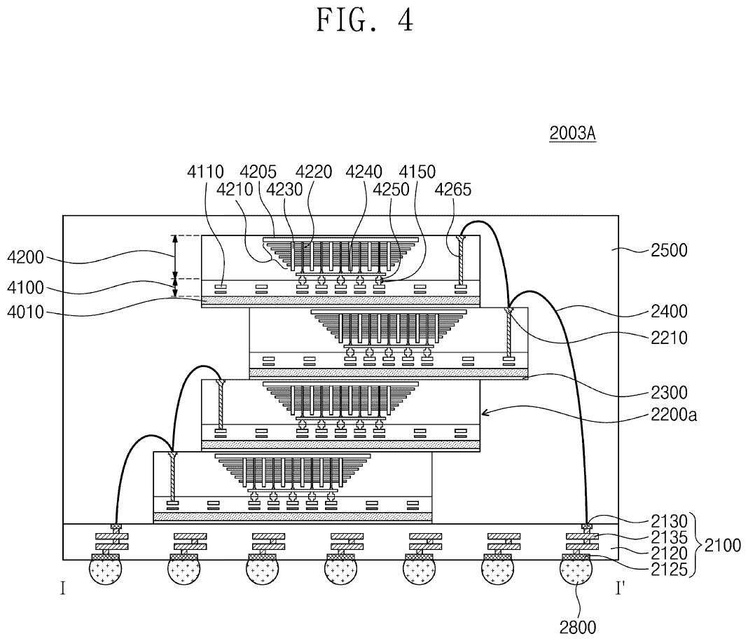

FIGS. 3 and 4 are cross-sectional views schematically illustrating semiconductor packages according to implementations. FIGS. 3 and 4 each illustrate some implementations of the semiconductor package of FIG. 1, and conceptually represent a region which is taken along a line I-I′.

Referring to FIG. 3, in the semiconductor package 2003, the package substrate 2100 may be a printed circuit board. The package substrate 2100 may include a package substrate body portion 2120, the package upper pads 2130 (e.g., of FIG. 2), which are disposed on an upper surface of the package substrate body portion 2120, lower pads 2125, which are disposed on or exposed through a lower surface of the package substrate body portion 2120, and internal lines 2135, which are provided in the package substrate body portion 2120 to electrically connect the package upper pads 2130 to the lower pads 2125. The package upper pads 2130 may be electrically connected to the connection structures 2400. The lower pads 2125 may be connected to the interconnection patterns 2005, which are provided in the main substrate 2001 of the electronic system 2000, through conductive connecting portions 2800, as shown in FIG. 2.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral lines 3110 are provided. The second structure 3200 may include a source structure 3205, the stack 3210 on the source structure 3205, the vertical structures 3220 and separation structures 3230 penetrating the stack 3210, bit lines 3240 electrically connected to the vertical structures 3220, and cell contact plugs electrically connected to the word lines WL (e.g., of FIG. 1) of the stack 3210. Each of the first and second structures 3100 and 3200 and the semiconductor chips 2200 may further include separation structures to be described below.

Each of the semiconductor chips 2200 may include penetration lines 3245, which are electrically connected to the peripheral lines 3110 of the first structure 3100 and are extended into the second structure 3200. The penetration line 3245 may be disposed outside the stack 3210, and in some implementations, the penetration line 3245 may be provided to further penetrate the stack 3210. Each of the semiconductor chips 2200 may further include an input/output connection line 3265 which is electrically connected to the peripheral line 3110 of the first structure 3100 and extending into the second structure 3200, and the input/output pad 2210 which is electrically connected to the peripheral line 3110 of the first structure 3100.

Referring to FIG. 4, in a semiconductor package 2003A, each of semiconductor chips 2200a may include a semiconductor substrate 4010, a first structure 4100 on the semiconductor substrate 4010, and a second structure 4200, which is provided on the first structure 4100 and is bonded with the first structure 4100 in a wafer bonding manner.

The first structure 4100 may include a peripheral circuit region, in which a peripheral line 4110 and first junction structures 4150 are provided. The second structure 4200 may include a source structure 4205, a stack 4210 between the source structure 4205 and the first structure 4100, vertical structures 4220 and a separation structure 4230 penetrating the stack 4210, and second junction structures 4250, which are respectively and electrically connected to the vertical structures 4220 and the word lines WL (e.g., of FIG. 1) of the stack 4210. For example, the second junction structures 4250 may be electrically and respectively connected to the vertical structures 4220 and the word lines WL (e.g., of FIG. 1) through bit lines 4240, which are electrically connected to the vertical structures 4220, and cell contact plugs, which are electrically connected to the word lines WL (e.g., of FIG. 1). The first junction structures 4150 of the first structure 4100 may be in contact with and coupled to the second junction structures 4250 of the second structure 4200. The coupled portions of the first junction structures 4150 and the second junction structures 4250 may be formed of or include, for example, copper (Cu).

Each of the first and second structures 4100 and 4200 and the semiconductor chips 2200a may further include a source structure, as will be described below with reference to some implementations. Each of the semiconductor chips 2200a may further include the input/output pads 2210 (e.g., of FIG. 2), which are electrically connected to the peripheral lines 4110 of the first structure 4100. Each of the semiconductor chips 2200a may further include an input/output pad 2210 and an input/output connection line 4265 below the input/output pad 2210. The input/output connection line 4265 may be electrically connected to the peripheral lines 4110 of the first structure 4100.

The semiconductor chips 2200 or 2200a of FIG. 3 or 4 may be electrically connected to each other by the connection structures 2400, which are provided in the form of bonding wires. However, in some implementations, semiconductor chips, which are provided in the same semiconductor package as the semiconductor chips 2200 or 2200a of FIG. 3 or 4, may be electrically connected to each other by a connection structure including through silicon vias (TSVs).

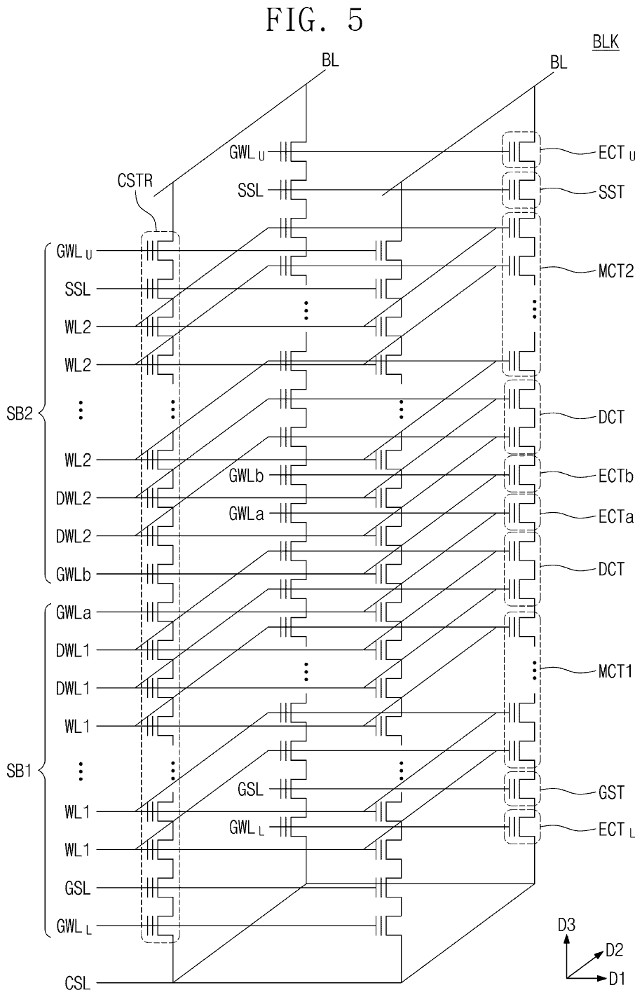

FIG. 5 is a circuit diagram illustrating a memory block of a semiconductor device according to some implementations.

Referring to FIG. 5, a memory block BLK of a semiconductor device according to implementations may include a plurality of sub-blocks SB1 and SB2, and an erase operation may be performed in units of sub-blocks SB1 and SB2.

The memory block BLK may include a plurality of cell strings CSTR configured as a NAND type, and may include memory cells arranged three-dimensionally.

More specifically, the memory block BLK may include a common source line CSL, a plurality of bit lines BL, and a plurality of cell strings CSTR disposed between the common source line CSL and the bit lines BL.

The cell strings CSTR may extend in a third direction D3 on a plane extending in first and second directions D1 and D2. The cell strings CSTR may be arranged two-dimensionally in the first and second directions D1 and D2 that intersect each other.

The bit lines BL may be spaced apart from each other in the first direction D1 and may extend in the second direction D2.

The plurality of cell strings CSTR may be connected in parallel to each of the bit lines BL. The plurality of cell strings CSTR may be commonly connected to a common source line CSL. That is, a plurality of cell strings CSTR may be disposed between a plurality of bit lines BL and one common source line CSL. A plurality of common source lines CSL may be arranged two-dimensionally. Here, the common source lines CSL may be electrically applied with the same voltage, or each of the common source lines CSL may be electrically controlled.

According to implementations, each of the cell strings CSTR may include lower and upper erase control transistors ECT_{L} and ECT_{U}, a string selection transistor SST, a ground selection transistor GST, first memory cell transistors MCT1, second memory cell transistors MCT2, first and second erase control transistors ECTa and ECTb, and dummy cell transistors DCT.

Each of memory cell transistors MCT1 and MCT2 may store one or more bits, and specifically, each memory cell may be used as a single level cell (SLC), a multi-level cell (MLC), a triple level cell (TLC), or a quadruple level cell (QLC).

In each of the cell strings CSTR, the upper erase control transistor ECT_{U} may be connected to the bit line BL, and the lower erase control transistor ECT_{L} may be connected to a common source line CSL.

The string selection transistor SST may be connected in series with the upper erase control transistor ECT_{U}, and the ground selection transistor GST may be connected in series with the lower erase control transistor ECT_{L.}

The first memory cell transistors MCT1 may be connected in series between the ground selection transistor GST and the first erase control transistor ECTa. The second memory cell transistors MCT2 may be connected in series between the string selection transistor SST and the second erase control transistor ECTb.

The first erase control transistor ECTa may be connected in series with the second erase control transistor ECTb.

At least one dummy cell transistor DCT may be connected between the first erase control transistor ECTa and the first memory cell transistors MCT1 and between the second erase control transistor ECTb and the second memory cell transistors MCT2.

The lower and upper erase control transistors ECT_{L} and ECT_{U} may be controlled by lower and upper erase control lines GWL_{L} and GWL_{U}. The first and second erase control transistors ECTa and ECTb may be controlled by the first and second erase control lines GWLa and GWLb.

The string selection transistor SST may be controlled by the string selection line SSL, and the first and second memory cell transistors MCT1 and MCT2 may be controlled by a plurality of word lines WL1 and WL2. In addition, the ground selection transistor GST may be controlled by the corresponding ground selection line GSL. The common source line CSL may be commonly connected to the sources of the lower erase control transistor ECT_{L}. The dummy cell transistors DCT may be controlled by dummy word lines DWL1 and DWL2.

The gate electrodes of the memory cells MCT arranged at substantially the same distance from the common source lines CSL may be commonly connected to one of the word lines WL1 and WL2 and may be in an equipotential state.

The ground selection lines GSL and the string selection lines SSL arranged at substantially the same level from the common source lines CSL may be electrically separated from each other.

In the memory block BLK, the number of cell strings CSTR, the number of word lines WL1 and WL2, the number of bit lines BL, the number of ground selection lines GSL, the number of string selection lines SSL, the number of dummy word lines DWL1 and DWL2, and the number of erase control lines GWLa, GWLb, GWL_{L}, and GWL_{U} may be variously changed according to the implementation.

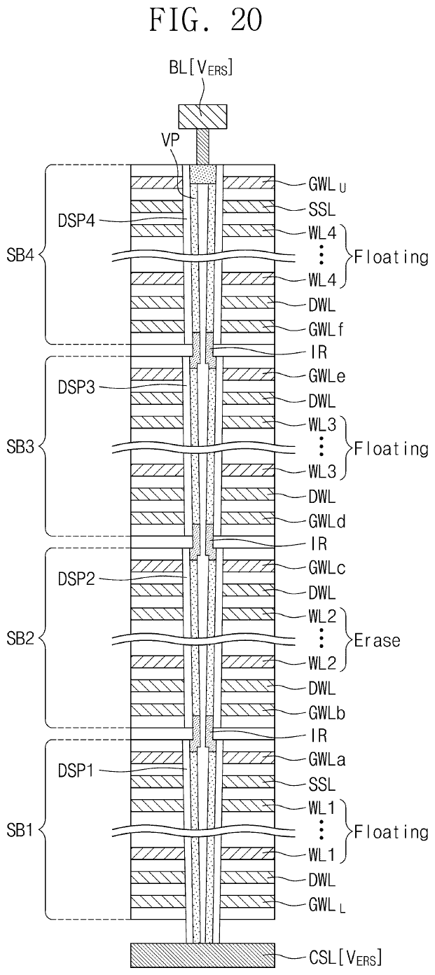

The lower and upper erase control transistors ECT_{L} and ECT_{U} and the first and second erase control transistors ECTa and ECTb may be used for an erase operation that erases data stored in the memory cell transistors MCT1 and MCT2 by utilizing the gate induced drain leakage (GIDL) phenomenon. In addition, the first and second erase control transistors ECTa and ECTb may be utilized, thereby an erase operation may be performed by dividing each memory block BLK into sub-blocks SB1 and SB2. The erase operation of the semiconductor device according to some implementations will be described in more detail later with reference to FIG. 20.

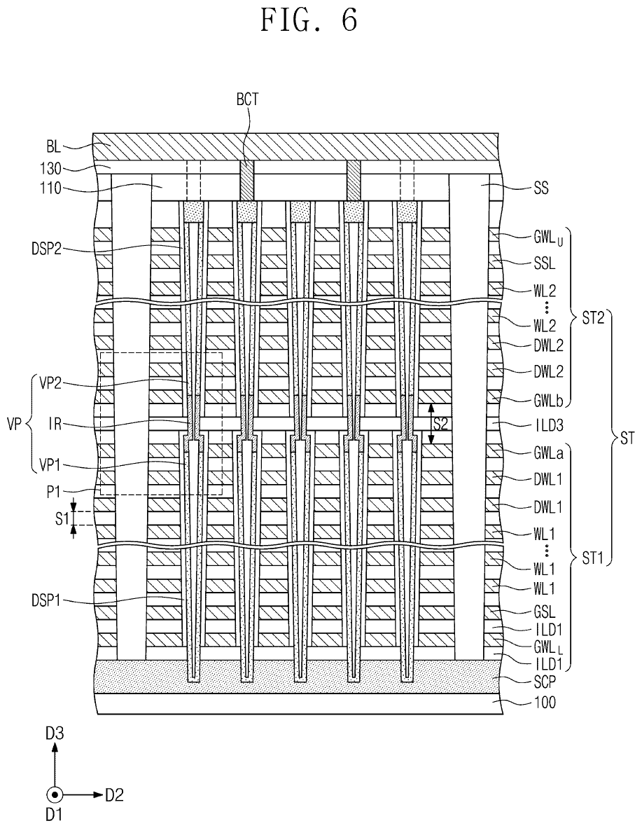

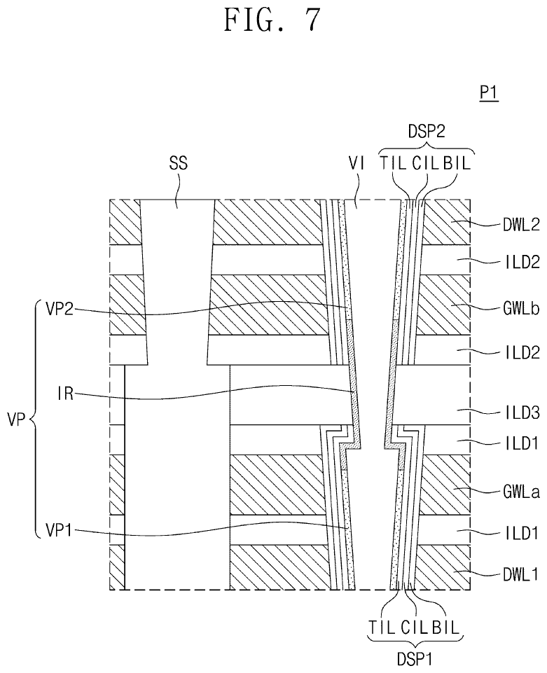

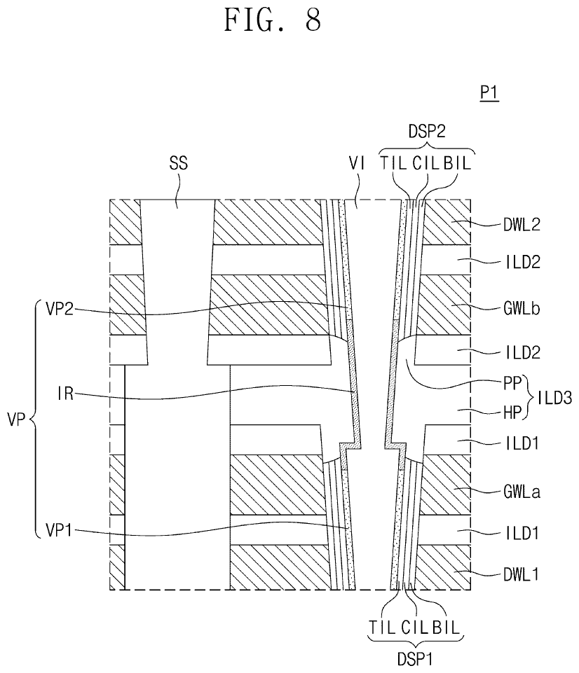

FIG. 6 is a cross-sectional view illustrating a portion of a semiconductor device according to some implementations. FIGS. 7 and 8 are enlarged views of portion ‘P1’of FIG. 6.

Referring to FIG. 6, a semiconductor device according to implementations may include a substrate 100, a source conductive pattern SCP, a stacked structure ST, vertical channels VP, data storage patterns DSP1 and DSP2, and bit lines BL.

According to some implementations, cell strings CSTR illustrated in FIG. 5 may be integrated on the substrate 100. The stacked structure ST and vertical channels VP may form the cell strings CSTR illustrated in FIG. 5.

More specifically, the substrate 100 may be made of a semiconductor material, and may include at least one of, for example, silicon (Si), germanium (Ge), silicon germanium (SiGe), gallium arsenide (GaAs), indium gallium arsenide (InGaAs), aluminum gallium arsenide (AlGaAs), or a mixture thereof. The substrate 100 may include a semiconductor doped with dopants having a first conductivity type (e.g., n-type) and/or an intrinsic semiconductor that is not doped with impurities. The substrate 100 may have a crystal structure including at least one selected from single crystal, amorphous, and polycrystalline.

The source conductive pattern SCP may be disposed between the stacked structure ST and the substrate 100. The source conductive pattern SCP may be parallel to the upper surface of the substrate 100 and may extend in a first direction D1 parallel to the stacked structure ST.

The source conductive pattern SCP may correspond to a common source line CSL of FIG. 5. The source conductive pattern SCP may include at least one selected from, for example, a doped semiconductor (e.g., doped silicon), a metal (e.g., tungsten, molybdenum, nickel, copper, aluminum, etc.), a conductive metal nitride (e.g., titanium nitride, tantalum nitride, etc.), or a transition metal (e.g., titanium, tantalum, etc.). As an example, the source conductive pattern SCP may include a metal material (e.g., tungsten).

A plurality of stacked structure ST may be provided. The plurality of stacked structures ST may extend in the first direction D1 and be spaced apart from each other in the second direction D2 when viewed in a plan view. Hereinafter, for convenience of explanation, a single stacked structure ST will be described.

The stacked structure ST may include conductive patterns and interlayer insulating layers alternately stacked in the third direction D3 (i.e., a vertical direction) that is perpendicular to the first and second directions D1 and D2 that intersect each other.

In implementations, the stacked structure ST may include a first sub-stack ST1 and a second sub-stack ST2 on the first sub-stack ST1. The first sub-stack ST1 may include first interlayer insulating layers ILD1 and first conductive patterns GWL_{L}, GSL, WL1, DWL1, and GWLa that are alternately stacked, and the second sub-stack ST2 may include second interlayer insulating layers ILD2 and second conductive patterns GWLb, DWL2, WL2, SSL, and GWL_{U} that are alternately stacked.

The first and second conductive patterns GWL_{L}, GSL, WL1, DWL1, GWLa, GWLb, DWL2, WL2, SSL, and GWL_{U} of the stacked structure ST may include at least one selected from, for example, a doped semiconductor (e.g., doped silicon), a metal (e.g., tungsten, molybdenum, nickel, copper, aluminum, etc.), a conductive metal nitride (e.g., titanium nitride, tantalum nitride, etc.), or a transition metal (e.g., titanium, tantalum, etc.). The first and second interlayer insulating layers ILD1 and ILD2 may include silicon oxide, silicon nitride, silicon oxynitride, and/or a low-k material. For example, the first and second interlayer insulating layers ILD1 and ILD2 may be formed using high-density plasma oxide (HDP oxide) or TetraEthylOrthoSilicate (TEOS).

In some implementations, the first conductive patterns of the first sub-stack ST1 may include a lower erase control line GWL_{L}, a ground selection line GSL, first word lines WL1, first dummy word lines DWL1, and a first erase control line GWLa.

The lower erase control line GWL_{L} may be adjacent to the source conductive pattern SCP and may be used as gate patterns of lower erase control transistors ECT_{L} (see FIG. 5) that control an erase operation by generating gate-induced drain leakage (GIDL) at a lower portion of the cell string CSTR (see FIG. 5).

The ground selection line GSL may be used as gate patterns of ground selection transistors GST (see FIG. 5) that control an electrical connection between a common source line CSL (see FIG. 5) and the vertical channel VP.

The first word lines WL1 may be used as gate patterns of the first memory cell transistors MCT1 (see FIG. 5).

The first erase control line GWLa may be used as gate patterns of the first erase control transistors ECTa (see FIG. 5) that control the erase operation by generating gate-induced drain leakage (GIDL) at a middle portion of the cell string CSTR (see FIG. 5).

The first dummy word lines DWL1 may be disposed between the first erase control line GWLa and the first word lines WL1.

In some implementations, the second conductive patterns of the second sub-stack ST2 may include a second erase control line GWLb, a second dummy word line DWL2, second word lines WL2, a string selection line SSL, and an upper erase control line GWL_{U.}

The second erase control line GWLb may be adjacent to the first erase control line GWLa and may be used as gate patterns of second erase control transistors ECTb (see FIG. 5) that control an erase operation by generating gate-induced drain leakage (GIDL) at the middle portion of a cell string CSTR (see FIG. 5).

The second word lines WL2 may be used as gate patterns of second memory cell transistors MCT2 (see FIG. 5). The second dummy word lines DWL2 may be disposed between the second erase control line GWLb and the second word lines WL2.

The string selection lines SSL may be used as gate patterns of string selection transistors SST (see FIG. 5) that control electrical connections between bit lines BL and vertical channels VP.

The upper erase control line GWL_{U} is adjacent to the bit line BL and may be used as gate patterns of upper erase control transistors ECT_{U} (see FIG. 5) that control erase operations by generating gate-induced drain leakage (GIDL) at an upper portion of the cell string CSTR (see FIG. 5).

In the drawings, the stacked structure ST is illustrated as including first and second sub-stacks ST1 and ST2, but implementations are not limited thereto, and the stacked structure ST may include two or more sub-stacks that are vertically stacked.

In each of the first and second sub-stacks ST1 and ST2, the conductive patterns adjacent to each other in the third direction D3 may be spaced apart by a first spacing S1. In the stacked structure ST, the first and second erase control lines GWLa and GWLb adjacent to each other in the third direction D3 may be spaced apart by a second spacing S2 greater than the first spacing S1.

According to some implementations, an intermediate insulating layer ILD3 may be disposed between the first sub-stack ST1 and the second sub-stack ST2. More specifically, the intermediate insulating layer ILD3 may be disposed between the uppermost first interlayer insulating layer ILD1 of the first sub-stack ST1 and the lowermost second interlayer insulating layer ILD2 of the second sub-stack ST2. A thickness of the intermediate insulating layer ILD3 may be substantially the same as a thickness of each conductive pattern of the stacked structure ST. The intermediate insulating layer ILD3 may include, for example, silicon oxide, silicon nitride, silicon oxynitride, and/or a low-k material.

A plurality of vertical channels VP may penetrate the stacked structure ST and be connected to the source conductive pattern SCP. The vertical channels VP may be arranged in a matrix form or in a zigzag form when viewed in a plan view.

In some implementations, each of the vertical channels VP may be provided in a vertical channel hole penetrating the stacked structure ST. In implementations, the vertical channel hole may include a first vertical channel hole penetrating the first sub-stack ST1 and second vertical channel holes penetrating the second sub-stack ST2 and connected to the first vertical channel holes.

Each of the vertical channels VP may include a first vertical portion VP1 in a first vertical channel hole and a second vertical portion VP2 in a second vertical channel hole. The first vertical portion VP1 and the second vertical portion VP2 may be a single structure that extends continuously without an interface. Here, the first vertical portion VP1 may have a sidewall having a uniform slope from a lower portion thereof to an upper portion thereof. Similarly, the second vertical portion VP2 may have a sidewall having a uniform slope from a lower portion thereof to an upper portion thereof. In other words, each of the first and second vertical portions VP1 and VP2 may have a width that increases in the first direction D1 or the second direction D2 as it moves away from the substrate 100. The first vertical portion VP1 and the second vertical portion VP2 may have different diameters at a portion where they are connected to each other. A step may be formed at a portion where the first vertical portion VP1 and the second vertical portion VP2 are connected to each other.

However, implementations are not limited thereto, and each of the vertical channels VP may have three or more vertical portions each having a step at two or more interfaces. In another example, each of the vertical channels VP may have flat sidewalls without a step.

The vertical channel VP may have a pipe shape or a cylinder shape with the top and bottom open. Alternatively, the vertical channel VP may have a pipe shape, a cylindershape, or a U-shape with the bottom closed. The vertical channel VP may have an inner sidewall defining an internal space and an outer sidewall adjacent to the stacked structure ST. The vertical channel VP may surround the outer sidewall of a gapfill insulating pattern VI.

The vertical channels VP may include a semiconductor material such as silicon (Si), germanium (Ge), or a mixture thereof. Additionally, the vertical channels VP may be an intrinsic semiconductor in a doped semiconductor or an impurity-free state. The vertical channels VP may include a polycrystalline semiconductor material. The vertical channels VP including the semiconductor material may be used as channels of the transistors constituting the cell string CSTR described with reference to FIG. 5.

In some implementations, each of the vertical channels VP may include an impurity region IR doped with an impurity of a first conductivity type (e.g., n-type) at a portion where the first vertical portion VP1 and the second vertical portion VP2 are connected to each other. The impurity region IR may include, for example, at least one of phosphorus (P), arsenic (As), and antimony (Sb), which are n-type dopants. An impurity concentration in the impurity region IR may be higher than an impurity concentration in the first and second vertical portions VP1 and VP2 of the vertical channel VP.

More specifically, referring to FIG. 7, the impurity regions IR of the vertical channels VP may be adjacent to the intermediate insulating layer ILD3 and may be surrounded by the intermediate insulating layer ILD3. The intermediate insulating layer ILD3 may be in direct contact with the impurity regions IR of the vertical channels VP. The impurity regions IR may extend vertically and overlap the first erase control line GWLa of the first sub-stack ST1 and may overlap the second erase control line GWLb of the second sub-stack ST2.

In the third direction D3, the lowest level of the impurity regions IR may be between the upper surface and the lower surface of the first erase control line GWLa, and the highest point of the impurity regions IR may be between the upper surface and the lower surface of the second erase control line GWLb.

As another example, referring to FIG. 8, the intermediate insulating layer ILD3 may include a horizontal portion HP parallel to the upper surface of the substrate 100 and a protrusion PP that is in contact with a portion of the sidewall of the vertical channel VP and protrudes vertically from the horizontal portion HP. The protrusion PP of the intermediate insulating layer ILD3 may be adjacent to the first and second erase control lines GWLa and GWLb. The protrusion PP of the intermediate insulating layer ILD3 may be in direct contact with the impurity region IR. The protrusion PP of the intermediate insulating layer ILD3 may have rounded upper and lower surfaces. The upper surface of the protrusion PP of the intermediate insulating layer ILD3 may be positioned at a level as high as or higher than the lower surface or the upper surface of the lowermost second interlayer insulating layer ILD2. The lower surface of the protrusion PP of the intermediate insulating layer ILD3 may be positioned at a level lower than the upper surface or the lower surface of the uppermost first interlayer insulating layer ILD1.

A first data storage pattern DSP1 may penetrate the first sub-stack ST1 and surround the sidewall of the first vertical portion VP1 of the vertical channel VP. A second data storage pattern DSP2 may penetrate the second sub-stack ST2 and surround the second vertical portion VP2 of the vertical channel VP. The first data storage pattern DSP1 and the second data storage pattern DSP2 may be vertically separated from each other by the intermediate insulating layer ILD3.

Referring to FIG. 7, each of the first and second data storage patterns DSP1 and DSP2 may be composed of one thin layer or a plurality of thin layers. In some implementations, the data storage pattern DSP may include a tunnel insulating layer TIL, a charge storage layer CIL, and a blocking insulating layer BIL sequentially stacked on the sidewall of the vertical channel VP as a data storage layer of a NAND flash memory device. For example, the charge storage layer CIL may be an insulating layer including a trap insulating layer, a floating gate electrode, or conductive nano dots. More specifically, the charge storage layer CIL may include at least one of a silicon nitride layer, a silicon oxide nitride layer, a Si-rich nitride layer, nanocrystalline Si, and a laminated trap layer. The tunnel insulating layer TIL may be one of materials having a larger band gap than the charge storage layer CIL, and the blocking insulating layer BIL may be a high-k layer such as an aluminum oxide layer and a hafnium oxide layer.

Furthermore, a horizontal insulating pattern may be provided between one sidewall of the conductive patterns GWLa, GWLb, DWL1, and DWL2 and the data storage pattern DSP. The horizontal insulating pattern may extend from upper and lower surfaces of the sidewalls of the conductive patterns GWLa, GWLb, DWL1, and DWL2. The horizontal insulating pattern may include a high-k dielectric layer, such as a blocking insulating layer BIL.

Referring to FIG. 8, the first and second data storage patterns DSP1 and DSP2 may be in contact with the protrusions PP of the intermediate insulating layer ILD3. A contact surface of the first and second data storage patterns DSP1 and DSP2 and the intermediate insulating layer ILD3 may have various shapes depending on the manufacturing process.

Referring again to FIG. 6, the stacked structure ST may be disposed between separation structures SS extending in parallel in the first direction D1. The separation structures SS may include an insulating material, such as silicon oxide, for example. The separation structures SS may include a lower vertical portion penetrating the first sub-stack ST1 and an upper vertical portion penetrating the second sub-stack ST2 and the intermediate insulating layer ILD3. Each of the lower and upper vertical portions may have a width that increases in the first direction D1 or the second direction D2 as the lower and upper vertical portions moves away from the substrate 100. In addition, a step may be formed at a portion where the lower and upper vertical portions are connected to each other.

A first upper insulating layer 110 may be disposed on the stacked structure ST and may cover upper surfaces of the vertical channels VP. A second upper insulating layer 130 may be disposed on the first upper insulating layer 110, and bit lines BL extending in the second direction D2 may be disposed on the second upper insulating layer 130. The bit lines BL may be connected to the bit line conductive pads on an upper end of the vertical channels VP through bit line contact plugs BCT. The bit line conductive pad may be made of an undoped semiconductor material, a doped semiconductor material, or a conductive material.

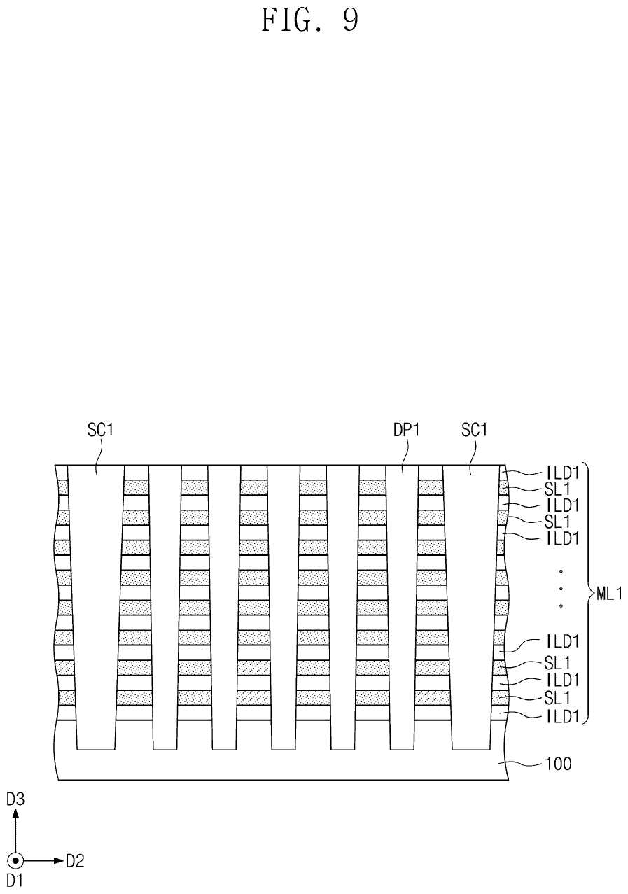

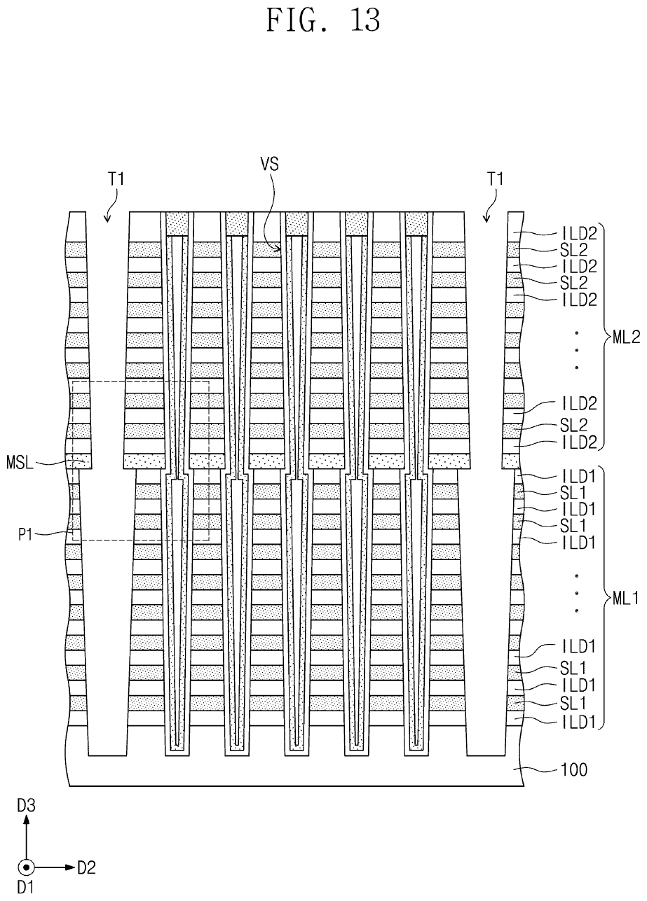

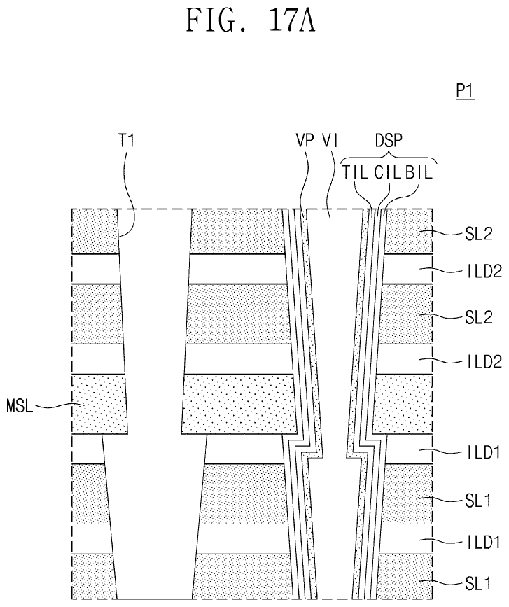

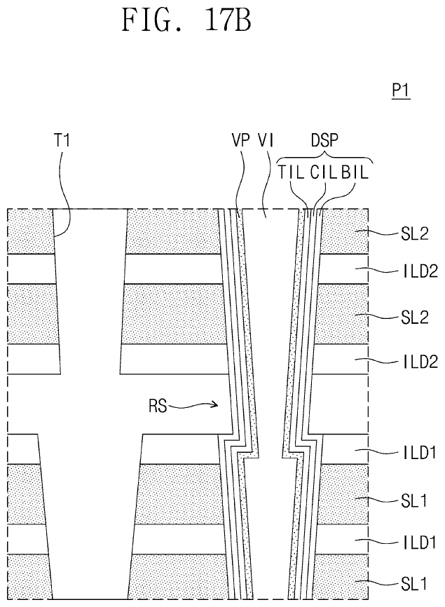

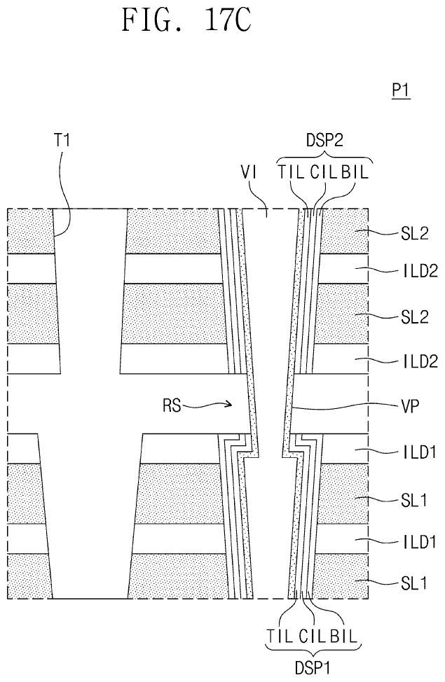

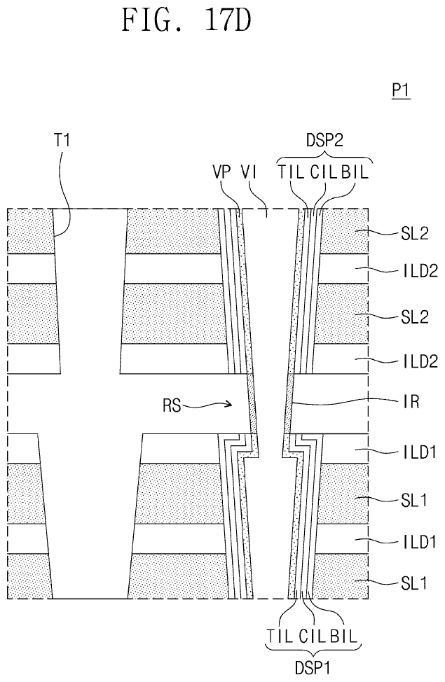

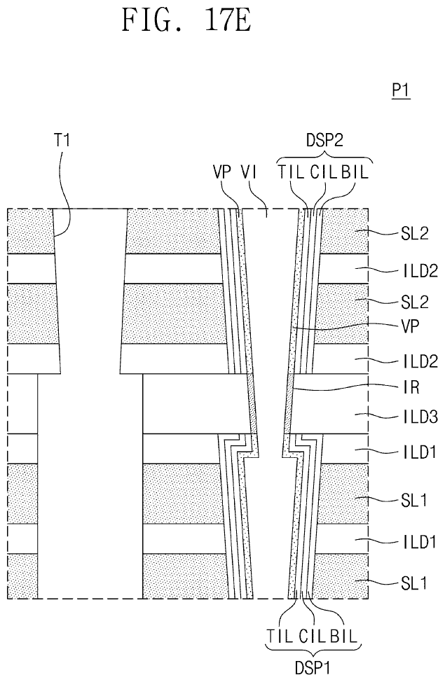

FIGS. 9 to 16 are cross-sectional views for explaining a method for manufacturing a semiconductor device according to some implementations. FIGS. 17A to 17E are drawings illustrating in detail a method for manufacturing a semiconductor device according to implementations and are enlarged views of portions ‘P1’ of FIGS. 13, 14, and 15.

Referring to FIG. 9, a first mold structure ML1 may be formed on a substrate 100 (or semiconductor layer).

The substrate 100 may be formed by depositing a semiconductor material. The substrate 100 may include, for example, at least one of silicon (Si), germanium (Ge), silicon germanium (SiGe), gallium arsenide (GaAs), indium gallium arsenide (InGaAs), aluminum gallium arsenide (AlGaAs), or a mixture thereof. The substrate 100 may include an intrinsic semiconductor that is doped with impurities and/or an intrinsic semiconductor that is not doped with impurities. The substrate 100 may have a crystal structure that includes at least one selected from single crystal, amorphous, and polycrystalline.

As another example, the substrate 100 may include a metal such as tungsten, a conductive metal nitride, a conductive metal silicide, a conductive metal oxide, or a combination thereof. As another example, the substrate 100 may be made of an insulating material.

Forming the first mold structure ML1 may include vertically and alternately stacking first interlayer insulating layers ILD1 and first sacrificial layers SL1.

In the first mold structure ML1, the first sacrificial layers SL1 may be formed of a material that may be etched with etch selectivity with respect to the first interlayer insulating layers ILD1. For example, the first sacrificial layers SL1 may be formed of an insulating material different from the first interlayer insulating layers ILD1. For example, the first sacrificial layers SL1 may be formed of a silicon nitride layer, and the first interlayer insulating layers ILD1 may include silicon oxide, silicon oxynitride, and/or a low-k material.

The first interlayer insulating layers ILD1 and the first sacrificial layers SL1 may be deposited using a thermal chemical vapor deposition (Thermal CVD), a plasma enhanced CVD, a physical CVD, or an atomic layer deposition (ALD) process. The first interlayer insulating layers ILD1 and the first sacrificial layers SL1 may be deposited in-situ.

Subsequently, first sacrificial pillars DP1 and first sacrificial patterns SC1 penetrating the first mold structure ML1 may be formed.

Forming the first sacrificial pillars DP1 and the first sacrificial patterns SC1 may include forming first channel holes and first separation holes penetrating the first mold structure ML1, forming a sacrificial layer filling the first channel holes and the first separation holes, and planarizing the sacrificial layer so that an upper surface of the first mold structure ML1 is exposed. Here, the first channel holes may be formed to be spaced apart from each other in the first direction D1 and the second direction D2, and the first separation holes may be formed to be connected to each other in the first direction D1 and spaced apart from each other in the second direction D2. When viewed in a plan view, the first channel holes may be arranged in a matrix shape or in a zigzag shape. When viewed in a plan view, the first separation holes may have a circular, oval, bar, or trench shape having a long axis in the first direction D1 or the second direction D2.

The first sacrificial pillars DP1 and the first sacrificial patterns SC1 may be formed of a material having etch selectivity with respect to the first mold structure ML1. For example, the first sacrificial pillars DP1 and the first sacrificial patterns SC1 may include one of, for example, polysilicon, a material containing carbon (C), or a metal material (e.g., W, TiN, etc.). In some implementations, the first sacrificial pillars DP1 and the first sacrificial patterns SC1 may include a first metal material, for example, tungsten (W).

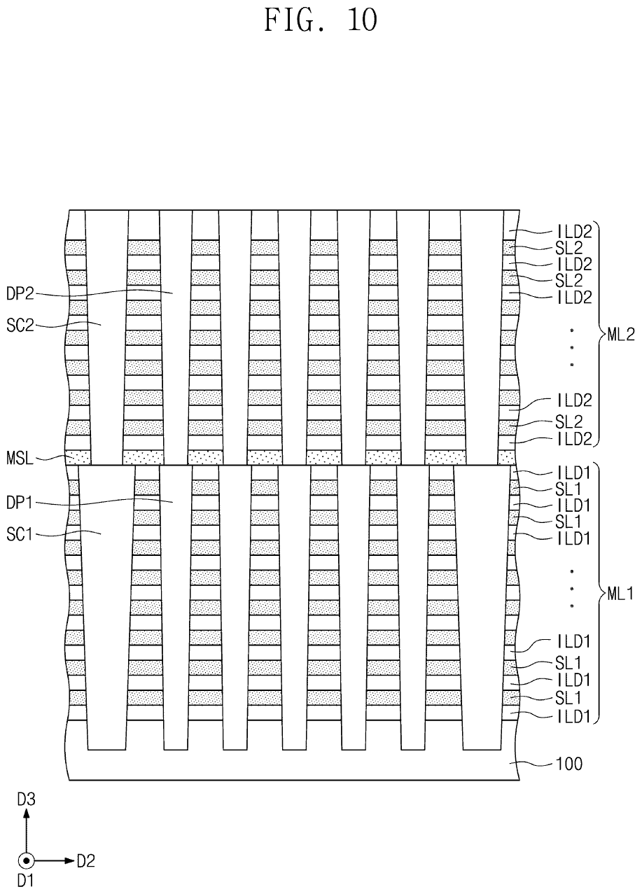

Referring to FIG. 10, an intermediate sacrificial layer MSL may be formed on the uppermost first interlayer insulating layer ILD1 of the first mold structure ML1.

The intermediate sacrificial layer MSL may be formed of a material having etch selectivity with respect to the first mold structure ML1. For example, the intermediate sacrificial layer MSL may be formed of a semiconductor material such as silicon (Si), germanium (Ge), silicon germanium (SiGe), a material containing carbon (C), or a metal material (e.g., W, TiN, etc.).

A second mold structure ML2 may be formed on the intermediate sacrificial layer MSL. The second mold structure ML2 may be formed by alternately and repeatedly stacking second interlayer insulating layers ILD2 and second sacrificial layers SL2 on the intermediate sacrificial layer MSL. In some implementations, the second sacrificial layers SL2 may be formed of the same material as the first sacrificial layers SL1, and the thickness of the second sacrificial layers SL2 may be substantially the same as the thickness of the first sacrificial layers SL1.

Forming the second mold structure ML2 may be substantially the same as forming the first mold structure ML1 as described above. That is, the second sacrificial layers SL2 may be formed of an insulating material different from the second interlayer insulating layers ILD2. The second sacrificial layers SL2 may be formed of the same material as the first sacrificial layers SL1. For example, the second sacrificial layers SL2 may be formed of a silicon nitride layer, and the second interlayer insulating layers ILD2 may include, for example, silicon oxide, silicon oxynitride, and/or a low-k material.

After forming the second mold structure ML2, second sacrificial pillars DP2 and second sacrificial patterns SC2 may be formed through the second mold structure ML2 and the intermediate sacrificial layer MSL. The second sacrificial pillars DP2 may be in contact with the first sacrificial pillars DP1, respectively, and the second sacrificial layers SL2 may be in contact with the first sacrificial layers SL1, respectively.

Forming the second sacrificial pillars DP2 and the second sacrificial patterns SC2 may include forming second channel holes and second separation holes penetrating the second mold structure ML2 and the intermediate sacrificial layer MSL, forming a sacrificial layer filling the second channel holes and the second separation holes, and planarizing the sacrificial layer so that the upper surface of the second mold structure ML2 is exposed.

The second sacrificial pillars DP2 and the second sacrificial patterns SC2 may be formed of a material having etch selectivity with respect to the first mold structure ML1. The second sacrificial pillars DP2 and the second sacrificial patterns SC2 may include the same material as the first sacrificial pillars DP1 and the first sacrificial patterns SC1.

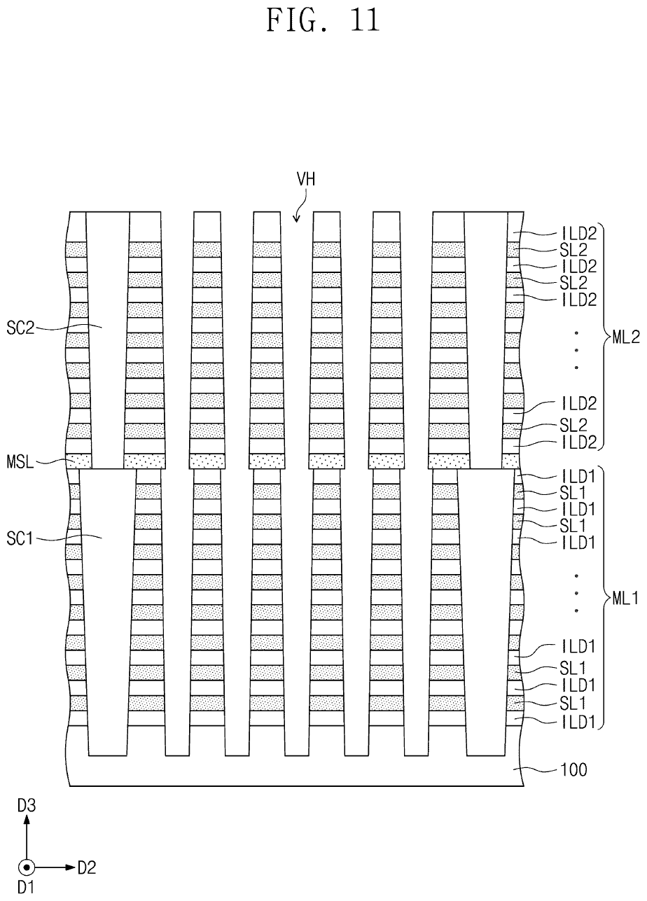

Referring to FIG. 11, after forming a mask pattern covering the second sacrificial layers SL2 on the second mold structure ML2, the second sacrificial pillars DP2 and the first sacrificial pillars DP1 may be sequentially removed to form vertical channel holes VH.

An etching process may be performed using an etching recipe having etch selectivity with respect to the first and second mold structures ML1 and ML2 and the intermediate sacrificial layer MSL to form the second sacrificial pillars DP2 and the first sacrificial pillars DP1.

Each of the vertical channel holes VH may include first channel holes penetrating the first mold structure ML1 and second channel holes penetrating the second mold structure ML2 and connected to the first channel holes. Here, each of the first and second channel holes may have a sidewall having a uniform slope from a lower portion thereof to an upper portion thereof. In addition, each of the vertical channel holes VH may have a step between the first and second channel holes.

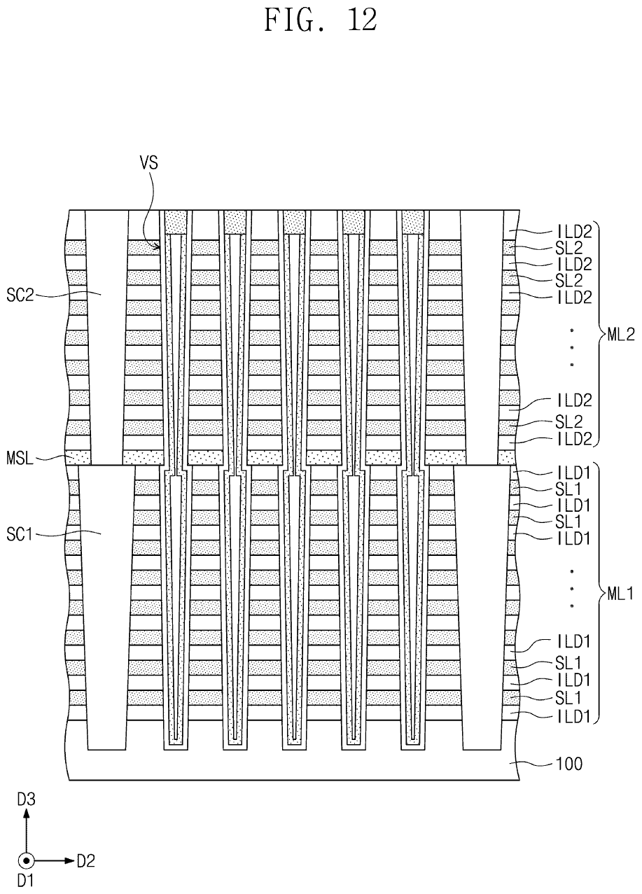

Referring to FIG. 12, vertical structures VS may be formed in the vertical channel holes VH penetrating the first and second mold structures ML1 and ML2.

Forming the vertical structures VS may include sequentially depositing a data storage layer and a vertical channel layer in the vertical channel holes, filling a gapfill insulating layer, and etching and planarizing the data storage layer and the vertical channel layer on the uppermost second interlayer insulating layer ILD2. Accordingly, a data storage layer DSP, a vertical channel VP, and a gapfill insulating pattern VI may be formed in each vertical channel hole. Upper surfaces of the vertical structures VS may be coplanar with an upper surface of the uppermost second interlayer insulating layer ILD2.

The data storage layer may be deposited on bottom surfaces and inner walls of the vertical channel holes VH with a uniform thickness using a chemical vapor deposition (CVD) or an atomic layer deposition (ALD) method. Referring to FIG. 17A, the data storage layer DSP may include a tunneling insulating layer TIL, a charge storage layer CIL, and a blocking insulating layer BIL that are sequentially stacked.

The vertical channel layer may be deposited on the data storage layer with a uniform thickness using a chemical vapor deposition (CVD) or atomic layer deposition (ALD) method. The vertical channel layer may include a semiconductor material such as silicon (Si), germanium (Ge), or a mixture thereof.

Subsequently, bit line conductive pads may be formed on an upper end of the vertical channel VP. The bit line conductive pads may be an impurity region doped with impurities or may be made of a conductive material. Upper surfaces of the bit line conductive pads may be coplanar with the upper surface of the uppermost second interlayer insulating layer ILD2.

Referring to FIG. 13, a first upper insulating layer 110 covering the vertical structures VS on the second mold structure ML2 and exposing the second sacrificial patterns SC2 may be formed. Thereafter, the second sacrificial patterns SC2 and the first sacrificial patterns SC1 may be sequentially removed to form separation trenches T1.

Each of the separation trenches T1 may include a first separation trench penetrating the first mold structure ML1 and a second separation trench penetrating the second mold structure ML2 and the intermediate sacrificial layer MSL and connected to the first separation trench. Referring to FIG. 17A, the separation trenches T1 may expose sidewalls of the first and second mold structures ML1 and ML2 and sidewall of the intermediate sacrificial layer MSL.

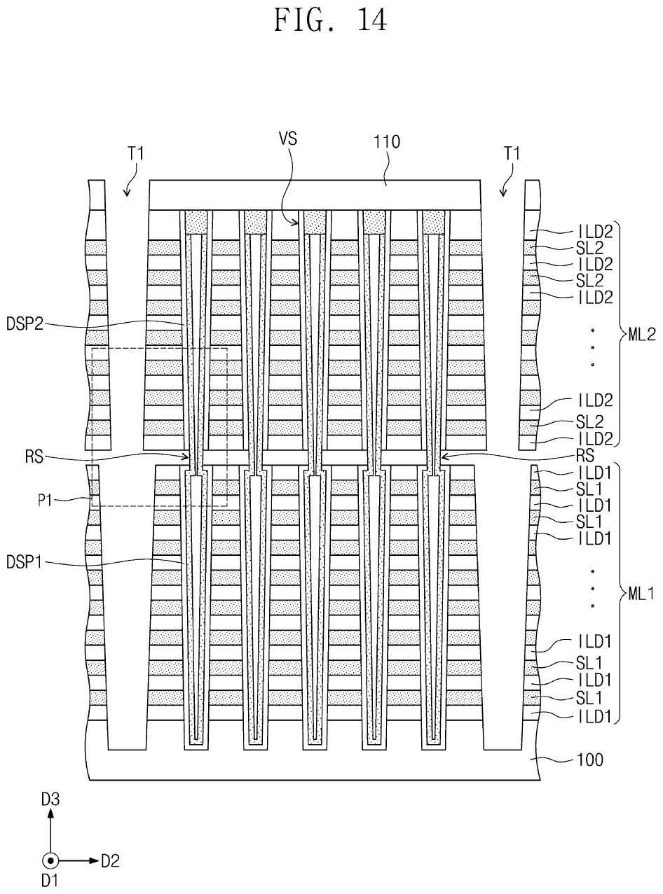

Referring to FIG. 14 and FIG. 17B, a recess region RS may be formed by selectively removing the intermediate sacrificial layer MSL exposed to the separation trenches T1.

The intermediate sacrificial layer MSL may be isotropically etched using an etching recipe that has etching selectivity with respect to the first and second mold structures ML1 and ML2 and the data storage layer DSP to form the recess region RS.

Referring to FIG. 17B, an isotropic etching process may be performed on the intermediate sacrificial layer MSL exposed to the separation trenches T1 to form the recess region RS that exposes a portion of the data storage layer DSP. In the isotropic etching process, an etching recipe that has etching selectivity with respect to the first and second mold structures ML1 and ML2 may be used for the recess region RS.

The recessed region RS may expose a portion of a sidewall of the data storage layer DSP of the vertical structure VS. The recessed region RS may extend horizontally from the separation trenches T1 between the first and second interlayer insulating layers ILD1 and ILD2. That is, a void may be formed between the first mold structure ML1 and the second mold structure ML2.

Referring to FIGS. 14 and 17C, after forming the recessed region RS, an isotropic etching process may be performed on portions of the data storage layer DSP exposed to the recessed region RS. Accordingly, portions of the sidewall of the vertical channel VP may be exposed. By performing the isotropic etching process on the data storage layer DSP, first and second data storage patterns DSP1 and DSP2 that are vertically spaced apart from each other may be formed.

The isotropic etching process for a data storage layer DSP may use an etching recipe having etch selectivity for the first and second mold structures ML1 and ML2. Specifically, the etching process for the data storage layer DSP may include isotropically etching sequentially the blocking insulating layer BIL, the charge storage layer CIL, and the tunnel insulating layer TIL exposed to a recess region RS.

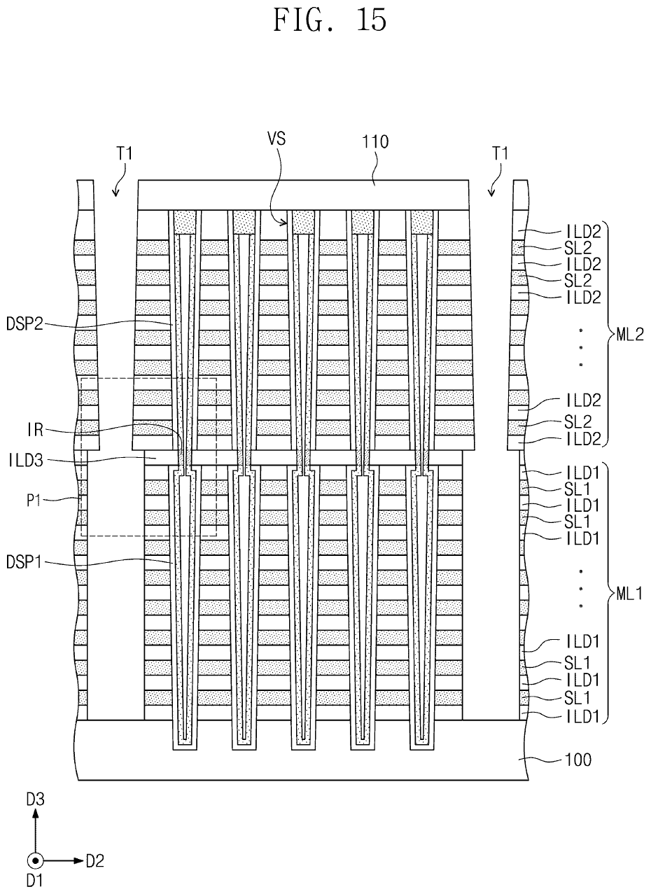

Referring to FIG. 15 and FIG. 17D, an impurity doping process may be performed through the recess region RS so that a first conductive type impurity may be doped in portions of the sidewalls of the vertical channel VP. Accordingly, an impurity region IR may be formed in the vertical channel VP adjacent to the recess region RS. In other words, the impurity region IR may be formed at a portion where the first vertical portion and the second vertical portion of the vertical channel VP are connected.

As the impurity doping process, a gas phase doping (GPD) process, a beam line ion implantation (BEI) process, and a plasma assisted doping (PLAD) process may be performed. After the impurity doping process, a heat treatment process may be performed.

During the impurity doping process, a gas containing impurities may be uniformly provided in the first separation trench T1 and the recess region RS. During the impurity doping process, a source gas including at least one of phosphorus (P), arsenic (As), and antimony (Sb) as type dopants may be used.

Referring to FIG. 15 and FIG. 17E, after forming the impurity region IR, an intermediate insulating layer ILD3 filling the recess region RS may be formed.

Forming the intermediate insulating layer ILD3 may include depositing an insulating layer that fills the recess region RS and conformally covers the inner sidewalls of the separation trenches T1, and then isotropically etching the insulating layer to re-expose the sidewalls of the first and second mold structures ML1 and ML2 to the separation trenches T1. Accordingly, the intermediate insulating layer ILD3 may be formed between the first and second mold structures ML1 and ML2 and may surround the impurity regions IR of the vertical channel VP.

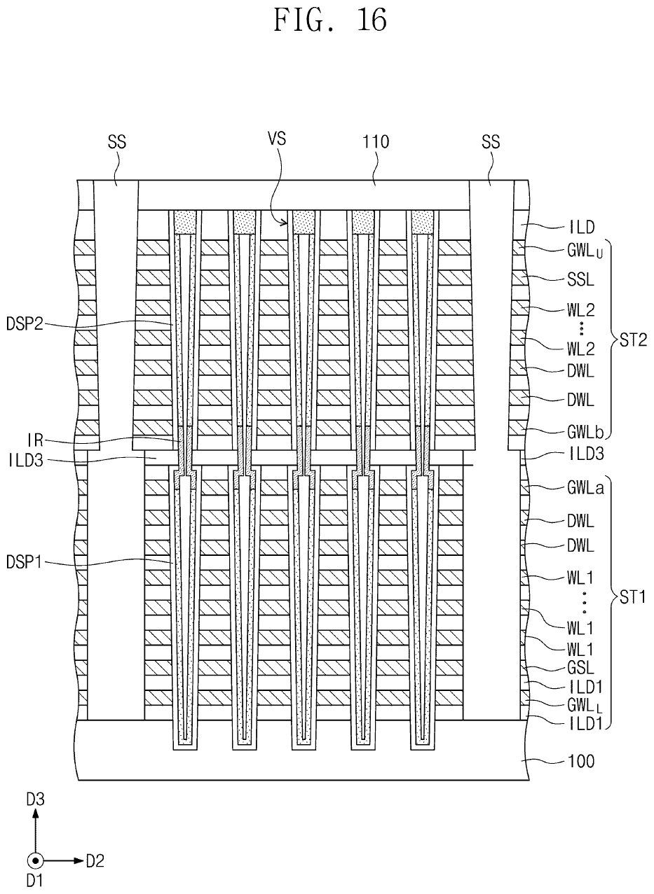

Referring to FIG. 16, the stacked structure ST described above may be formed by performing processes of replacing the sacrificial layers SL1 and SL2 with conductive patterns GWL_{L}, GSL, WL1, DWL, GWLa, GWLb, DWL, WL2, SSL, and GWL_{U}. Forming the stacked structure ST may include isotropically etching the first and second sacrificial layers SL1 and SL2 using an etching recipe having etch selectivity with respect to the first and second interlayer insulating layers ILD1 and ILD2 and the first and second data storage patterns DSP1 and DSP2, depositing a conductive layer filling an empty space from which the first and second sacrificial layers SL1 and SL2 are removed, and performing an isotropic etching process on the conductive layer to separate the conductive layer into a plurality of conductive patterns.

While forming the conductive patterns of the stacked structure ST, impurities may be diffused or annealed in the impurity region IR in the vertical channel VP. Accordingly, the impurity region IR may be vertically extended to be adjacent to the first erase control line GWLa and the second erase control line GWLb.

After forming the stacked structure ST, separation structures SS may be formed by filling an insulating material in the separation trenches T1. The separation structures SS may have a multi-layer structure or a single-layer structure. The separation structures SS may include at least one of silicon oxide, silicon nitride, or polysilicon.

Thereafter, as illustrated in FIG. 6, first and second upper insulating layers 110 and 130 may be formed on the stacked structure ST, and bit lines BL may be formed on the second upper insulating layer 130. The bit lines BL may be connected to the vertical channels VP through the bit line contact plugs BCT penetrating the first and second upper insulating layers 110 and 130.

Furthermore, a source conductive pattern SCP connected to the vertical channels VP may be formed under the stacked structure ST.

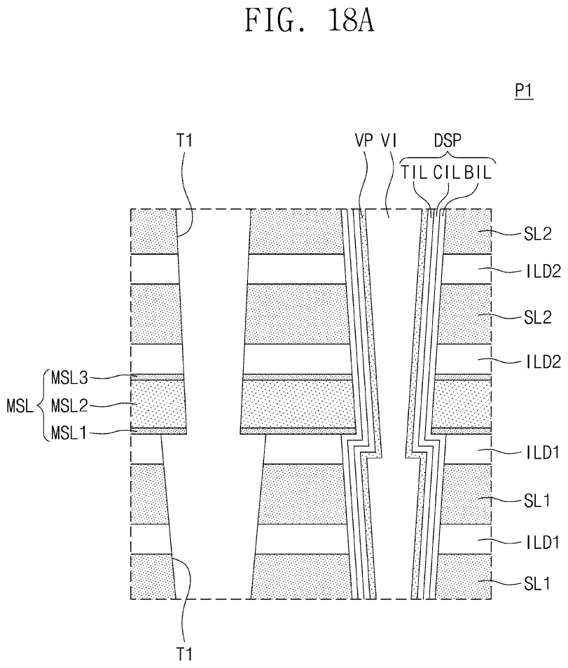

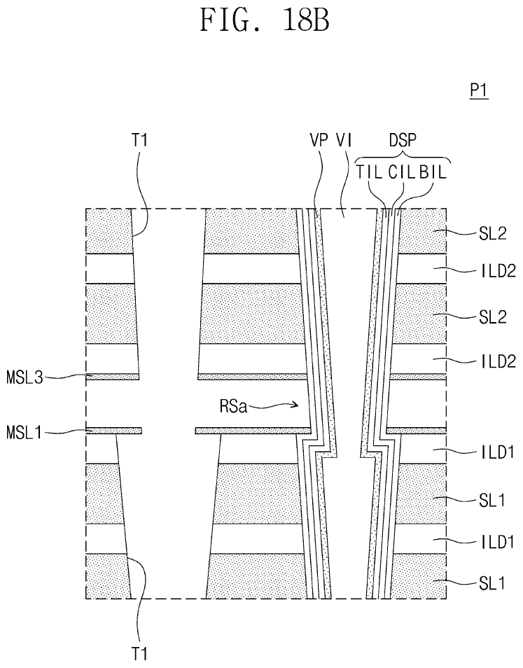

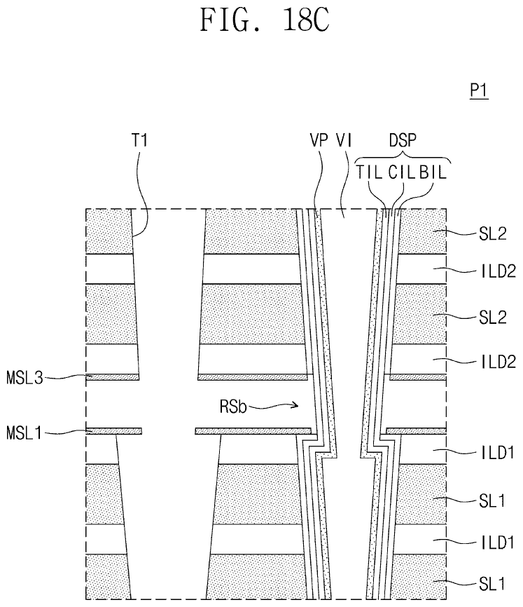

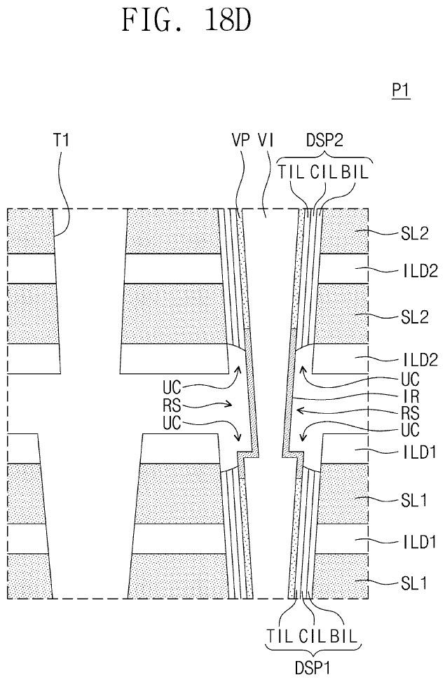

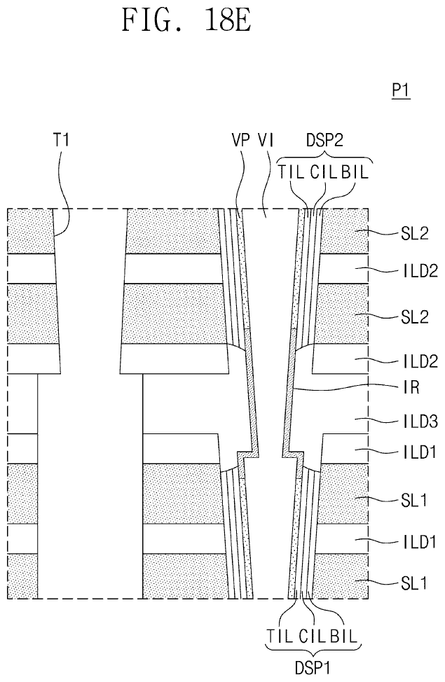

FIGS. 18A to 18E are drawings illustrating in detail a method for manufacturing a semiconductor device according to some implementations, and are enlarged views of portions ‘P1’ of FIGS. 13, 14, and 15. For the sake of simplicity of explanation, descriptions of technical features identical to those of the semiconductor device described above may be omitted, and differences will be described in detail.

Referring to FIG. 18A, the intermediate sacrificial layer MSL between the first mold structure ML1 and the second mold structure ML2 may include a first intermediate sacrificial layer MSL1, a second intermediate sacrificial layer MSL2, and a third intermediate sacrificial layer MSL3 that are sequentially stacked.

The first and third intermediate sacrificial layers MSL1 and MSL3 may include a material having etch selectivity with respect to the first and second interlayer insulating layers ILD1 and ILD2 and the second intermediate sacrificial layer MSL2. The first and third intermediate sacrificial layers MSL1 and MSL3 may include, for example, silicon nitride or silicon oxynitride. The first and third intermediate sacrificial layers MSL1 and MSL3 may have substantially the same thickness as a charge storage layer CIL of a data storage layer DSP.

The second intermediate sacrificial layer MSL2 may be formed of a material having etch selectivity with respect to the first and third intermediate sacrificial layers MSL1 and MSL3 and the data storage layer DSP. For example, the second intermediate sacrificial layer MSL2 may be formed of a material containing silicon (Si), germanium (Ge), silicon germanium (SiGe), carbon (C), or a metal material (e.g., W, TiN, etc.). The second intermediate sacrificial layer MSL2 may be thicker than the first and third intermediate sacrificial layers MSL1 and MSL3.

Referring to FIG. 18B, the second intermediate sacrificial layer MSL2 may be selectively removed through the separation trench T1 to form a first recess region RSa. The first recess region RSa may expose a blocking insulating layer BIL of the data storage layer DSP.

Referring to FIG. 18C, a first etching process may be performed to etch a portion of the blocking insulating layer BIL exposed to the first recess region RSa, and thus a second recess region RSb exposing a portion of the charge storage layer CIL may be formed. An etchant containing hydrofluoric acid or sulfuric acid may be used in the first etching process, and the tunnel insulating layer TIL of the data storage layer and the first and third intermediate sacrificial layers MSL1 and MSL3 may be used as etch stop layers during the first etching process. Accordingly, thickness reduction of the vertically adjacent first and second interlayer insulating layers ILD1 and ILD2 may be prevented.

Referring to FIG. 18D, a second etching process may be performed to etch a portion of the charge storage layer CIL exposed to the second recess region RSb, thereby exposing a portion of the tunnel insulating layer TIL. During the second etching process, the first and third intermediate sacrificial layers MSL1 and MSL3 may be etched to expose the first and second interlayer insulating layers ILD1 and ILD2. An etchant containing phosphoric acid may be used in the second etching process, and the tunnel insulating layer TIL may be used as an etch stop layer during the second etching process.

Subsequently, a third etching process may be performed to etch a portion of the tunnel insulating layer TIL exposed to the second recess region RSb, thereby exposing a portion of the vertical channel VP to the recess region RS.

As the first, second, and third etching processes are performed on the data storage layer through the recess region RS, an undercut region UC that exposes portions of the vertical channel layer VP may be formed. The undercut region UC may be a hollow space extending vertically from the recess region RS. The undercut region UC may be defined between the vertical channel layer VP and sidewalls of the first and second interlayer insulating layers ILD1 and ILD2.

By forming the undercut region UC, the data storage layer DSP may be separated into a first data storage pattern DSP1 and a second data storage pattern DSP2.

An upper surface of the first data storage pattern DSP1 and a lower surface of the second data storage pattern DSP2 may be defined. The upper surface of the first data storage pattern DSP1 and the lower surface of the second data storage pattern DSP2 may have a tapered shape. In addition, a level of a bottom surface of the second data storage pattern DSP2 and a level of an upper surface of the first data storage pattern DSP1 may be variously changed depending on the isotropic process for the data storage layer DSP.

Referring to FIG. 18E, after forming the impurity region IR, an intermediate insulating layer ILD3 filling the recess region RS and the undercut region UC may be formed. The intermediate insulating layer ILD3 may include a protrusion filled in the undercut region UC, as described above with reference to FIG. 8.

The intermediate insulating layer ILD3 may be formed using a chemical vapor deposition (CVD) process or an atomic layer deposition (ALD) process. The intermediate insulating layer ILD3 may include, for example, silicon oxide.

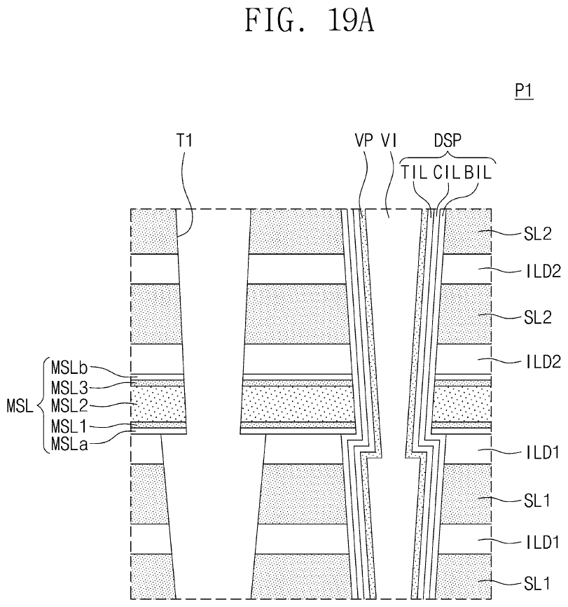

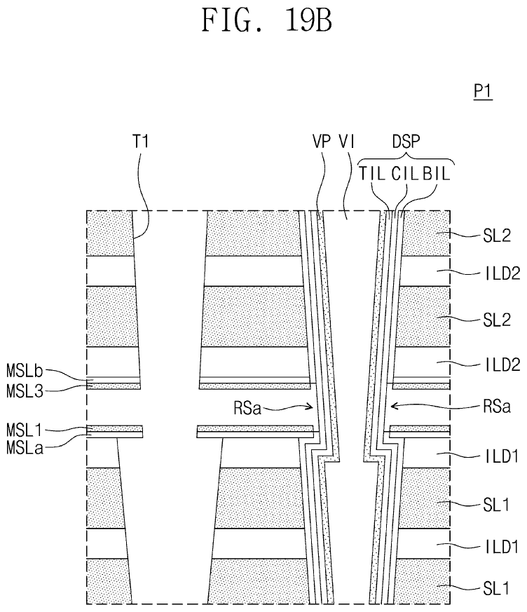

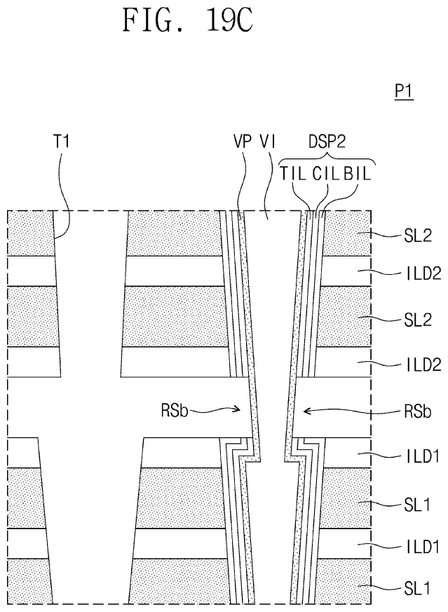

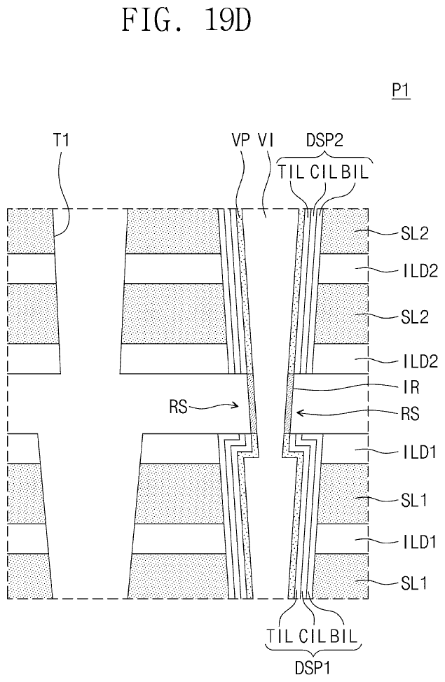

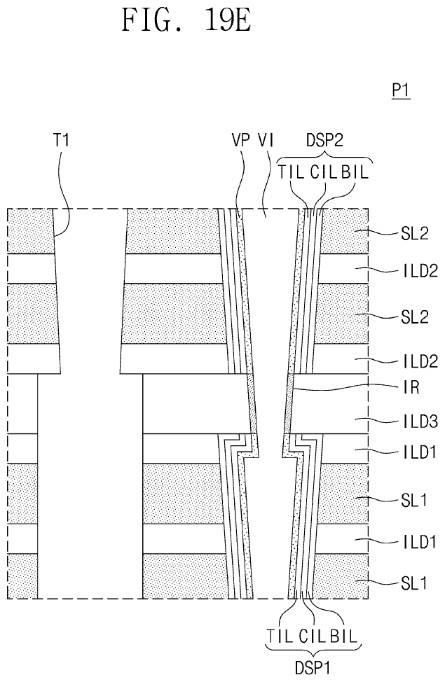

FIGS. 19A to 19E are drawings illustrating in detail a method for manufacturing a semiconductor device according to some implementations, and are enlarged views of portions ‘P1’ of FIGS. 13, 14, and 15. For the sake of brevity of explanation, descriptions of technical features identical to those of the semiconductor device described above may be omitted, and differences will be described in detail.

As described above with reference to FIG. 13, an intermediate sacrificial layer MSL may be disposed between the first mold structure ML1 and the second mold structure ML2. The intermediate sacrificial layer MSL may include a first intermediate sacrificial layer MSL1, a second intermediate sacrificial layer MSL2, and a third intermediate sacrificial layer MSL3 that are sequentially stacked, as illustrated in FIG. 19A. In addition, the intermediate sacrificial layer MSL may further include a first sub-sacrificial layer MSLa between the uppermost first interlayer insulating layer ILD1 and the first intermediate sacrificial layer MSL1, and a second sub-sacrificial layer MSLb between the lowermost second interlayer insulating layer ILD2 and the third intermediate sacrificial layer MSL3.

The first and third intermediate sacrificial layers MSL1 and MSL3 may include a material having etch selectivity with respect to the first and second interlayer insulating layers ILD1 and ILD2 and the second intermediate sacrificial layer MSL2. The first and third intermediate sacrificial layers MSL1 and MSL3 may include, for example, silicon nitride or silicon oxynitride. The first and third intermediate sacrificial layers MSL1 and MSL3 may have substantially the same thickness as the charge storage layer CIL of the data storage layer DSP.

The second intermediate sacrificial layer MSL2 may be formed of a material having etch selectivity with respect to the first and third intermediate sacrificial layers MSL1 and MSL3 and the data storage layer DSP. For example, the second intermediate sacrificial layer MSL2 may be formed of a material containing silicon (Si), germanium (Ge), silicon germanium (SiGe), carbon (C), or a metal material (for example, W, TiN, etc.). The second intermediate sacrificial layer MSL2 may be thicker than the first and third intermediate sacrificial layers MSL1 and MSL3.

The first and second sub-sacrificial layers MSLa and MSLb may include a material having etch selectivity with respect to the first and third intermediate sacrificial layers MSL1 and MSL3. The first and second sub-sacrificial layers MSLa and MSLb may include, for example, silicon oxide or silicon oxynitride. The first and third sub-sacrificial layers MSLa and MSLb may have substantially the same thickness as the tunnel insulating layer TIL of the data storage layer DSP.

Referring to FIG. 19B, the second intermediate sacrificial layer MSL2 exposed to the separation trenches T1 may be selectively removed to form a first recess region RSa.

The second intermediate sacrificial layer MSL2 may be isotropically etched using an etching recipe having etch selectivity with respect to the first and second mold structures ML1 and ML2 and the data storage layer DSP to form the first recess region RSa. Accordingly, the first recess region RSa may expose the blocking insulating layer BIL of the data storage layer DSP.

Subsequently, a portion of the blocking insulating layer BIL exposed to the first recess region RSa may be isotropically etched to expose a portion of the charge storage layer CIL. During the isotropic etching of a portion of the blocking insulating layer BIL, the first and third intermediate sacrificial layers MSL1 and MSL3 may be used as etch stop layers.

Thereafter, a portion of the charge storage layer CIL exposed to the first recess region RSa may be isotropically etched to expose a portion of the tunnel insulating layer TIL. During the etching of the charge storage layer CIL, the first and third intermediate sacrificial layers MSL1 and MSL3 may be etched together to expose the first and second sub-sacrificial layers MSLa and MSLb.

Then, referring to FIG. 19C, a portion of the tunnel insulating layer TIL exposed to the first recess region RSa may be etched to expose a portion of the sidewall of the vertical channel VP to the second recess region RSb. During the etching of a portion of the tunnel insulating layer TIL, the first and second sub-sacrificial layers MSLa and MSLb may prevent thicknesses change of the vertically adjacent first and second interlayer insulating layers ILD1 and ILD2.

By forming the second recess region RSb, the data storage layers DSP may be separated from each other to form the first and second data storage patterns DSP1 and DSP2.

Referring to FIG. 15 and FIG. 19D, an impurity region IR may be formed in a portion of the vertical channel VP by doping an impurity of the first conductive type through the second recess region RSb. As described above, the impurity region IR may be formed at a portion where the first vertical portion and the second vertical portion of the vertical channel VP are connected.

Referring to FIG. 15 and FIG. 19E, after forming the impurity region IR, an intermediate insulating layer ILD3 filling the second recess region RSb may be formed.

As described above, forming the intermediate insulating layer ILD3 may include depositing an insulating layer that fills the recess region RS and conformally covers the inner walls of the separation trenches T1, and then isotropically etching the insulating layer to re-expose the sidewalls of the first and second mold structures ML1 and ML2 to the separation trenches T1.

Thereafter, as described with reference to FIG. 16, processes for replacing the first and second sacrificial layers SL1 and SL2 with the conductive patterns GWL_{L}, GSL, WL1, DWL, GWLa, GWLb, DWL, WL2, SSL, and GWL_{U} may be performed.

FIG. 20 is a drawing for explaining an erase operation of a semiconductor device according to some implementations.

Descriptions of technical features identical to those of the semiconductor device described above may be omitted for brevity of explanation, and differences will be described in detail.

Referring to FIG. 20, a semiconductor device according to some implementations may include first to fourth sub-blocks SB1, SB2, SB3, and SB4 vertically stacked between a common source line CSL and a bit line BL.

According to some implementations, an erase operation of a semiconductor device may be performed in one of the first to fourth sub-blocks SB1, SB2, SB3, and SB4. FIG. 20 shows a bias condition for performing an erase operation in a second sub-block SB2 among the first to fourth sub-blocks SB1, SB2, SB3, and SB4.

The first sub-block SB1 may include a lower erase control line GWL_{L}, first word lines WL1, and a first erase control line GWLa that are sequentially stacked. The first sub-block SB1 may further include at least one dummy word line DWL between the first word lines WL1 and the lower and first erase control lines GWL_{L} and GWLa.

The second sub-block SB2 may include a second erase control line GWLb, second word lines WL2, and a third erase control line GWLc that are sequentially stacked. The second sub-block SB2 may further include at least one dummy word line DWL between the second word lines WL2 and the second and third erase control lines GWLb and GWLc, respectively.

The third sub-block SB3 may further include a fourth erase control line GWLd, a third word line WL3, and a fifth erase control line GWLe that are sequentially stacked. The third sub-block SB3 may further include at least one dummy word line DWL between the third word lines WL3 and the fourth and fifth erase control lines GWLd and GWLe, respectively.

The fourth sub-block SB4 may further include a sixth erase control line GWLf, a fourth word line WL4, and an upper erase control line GWL_{U} that are sequentially stacked. The fourth sub-block SB4 may further include at least one dummy word line DWL between the fourth word lines WL4 and the sixth and upper erase control lines GWLf and GWL_{U.}

The vertical channel VP may vertically penetrate the conductive patterns of the first to fourth sub-blocks SB1, SB2, SB3, and SB4 and may be electrically connected to the bit line BL and the common source line CSL. The vertical channel VP may include a first vertical portion penetrating the conductive patterns GWL_{L}, GSL, WL1, and GWLa of the first sub-block SB1, a second vertical portion penetrating the conductive patterns GWLb, WL2, and GWLc of the second sub-block SB2, a third vertical portion penetrating the conductive patterns GWLd, WL3, and GWLe of the third sub-block SB3, and a fourth vertical portion penetrating the conductive patterns GWLf, WL4, SSL, and GWL_{U} of the fourth sub-block SB4.

The vertical channel VP may include impurity regions IR doped with impurities of the first conductive type between the first and second vertical portions, between the second and third vertical portions, and between the third and fourth vertical portions, respectively.

A first data storage pattern DSP1 may penetrate the conductive patterns GWL_{L}, GSL, WL1, and GWLa of the first sub-block SB1 and may surround a sidewall of a first vertical portion of the vertical channel VP.

A second data storage pattern DSP2 may be vertically spaced from the first data storage pattern DSP1, may penetrate the conductive patterns GWLb, WL2, and GWLc of the second sub-block SB2, and may surround a sidewall of a second vertical portion of the vertical channel VP.

The third data storage pattern DSP3 may be vertically spaced apart from the second data storage pattern DSP2, may penetrate the conductive patterns GWLd, WL3, and GWLe of the third sub-block SB3, and may surround a sidewall of a third vertical portion of the vertical channel VP.

A fourth data storage pattern DSP4 may be vertically spaced apart from the third data storage pattern DSP3, may penetrate the conductive patterns GWLf, WL4, SSL, and GWL_{U} of the fourth sub-block SB4, and may surround a sidewall of a fourth vertical portion of the vertical channel VP.

Each of the first to fourth data storage patterns DSP1, DSP2, DSP3, and DSP4 may include a tunnel insulating layer, a charge storing layer, and a blocking insulating layer, which are sequentially stacked, as described above with reference to FIGS. 7 and 8.

In some implementations, an erase bias may be applied to corresponding conductive patterns to perform an erase operation on second memory cells included in the second sub-block SB2.

In detail, a predetermined voltage may be applied to the string selection line SSL and the ground selection line GSL to turn on the string selection transistor SST (see FIG. 5) and the ground selection transistor GST (see FIG. 5). Also, a turn-on voltage (or read voltage) may be applied to the erase control lines GWL_{L}, GWLd, GWLe, GWLf, and GWL_{U} and the word lines WL1, WL3, and WL4 in the unselected first, third, and fourth sub-blocks SB1, SB3, and SB4. Accordingly, the vertical channel VP adjacent to the second sub-block SB2 may be electrically connected to the bit line BL and the common source line CSL.

Thereafter, an erase voltage V_{ERS} may be applied to the bit line BL and the common source line CSL, and the string selection line SSL, the ground selection line GSL, the erase control lines GWL_{L}, GWLd, GWLe, GWLf, and GWL_{U} and the word lines WL1, WL3, and WL4 in the unselected first, third, and fourth sub-blocks SB1, SB3, and SB4 may be electrically floated. Accordingly, an erase operation is not performed on the memory cells of the unselected first, third, and fourth sub-blocks SB1, SB3, and SB4, while the erase voltage V_{ERS} may be transmitted to the vertical channel VP adjacent to the selected second sub-block SB2.

A GIDL voltage may be applied to the second and third erase control lines GWLb and GWLc of the selected second sub-block SB2. Here, the GIDL voltage may be less than the erase voltage V_{ERS} and greater than the ground voltage (Vss). The ground voltage or 0V may be applied to the second word lines WL2 and the dummy word lines DWL of the second sub-block SB2.

Since the vertical channel VP includes impurity regions IR doped with impurities of the first conductivity type between the first to fourth sub-blocks SB1, SB2, SB3, and SB4, a GIDL phenomenon may be induced between each of the first to fourth sub-blocks SB1, SB2, SB3, and SB4.

For example, when the GIDL voltage is applied to the second and third erase control lines GWLb and GWLc, a depletion region may be induced in portions of the vertical channel VP overlapping the second and third erase control lines GWLb and GWLc, and electron-hole pairs may be formed in the depletion region. Electrons of the electron-hole pairs may move toward the bit line BL and the common source line CSL by band-to-band tunneling mechanism, and holes may move to the vertical channel VP of the second sub-block SB2, thereby increasing channel voltage. The holes transferred to the vertical channel VP may be combined with electrons stored in the charge storage layer by tunneling due to a potential difference between the second word lines WL2 and the vertical channel VP. Accordingly, the erase operation may be performed on the memory cells of the second sub-block SB2.

According to some implementations, the impurity region doped with the first conductive type impurity in the middle portion of the vertical channel may be formed, and thus the gate-induced drain leakage (GIDL) current may be generated in the middle portion of the vertical channel. Accordingly, the erase operation may be performed for each of the sub-stacks, which is the portion of the stacked structure including the vertically stacked word lines.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While implementations are described above, a person skilled in the art may understand that many modifications and variations are made without departing from the spirit and scope of the disclosure defined in the following claims. Accordingly, the example implementations should be considered in all respects as illustrative and not restrictive, with the spirit and scope being indicated by the appended claims.

What is claimed is:

1. A semiconductor device comprising:
a substrate;
a first sub-stack including first interlayer insulating layers and first conductive patterns alternately stacked on the substrate;
a second sub-stack including second interlayer insulating layers and second conductive patterns alternately stacked on the first sub-stack;
an intermediate insulating layer between the first sub-stack and the second sub-stack;
a vertical channel extending through the first sub-stack and the second sub-stack and through the intermediate insulating layer;
a first data storage pattern extending through the first sub-stack and surrounding a first vertical portion of the vertical channel; and
a second data storage pattern extending through the second sub-stack and surrounding a second vertical portion of the vertical channel,
wherein the vertical channel includes an impurity region adjacent to the intermediate insulating layer, the impurity region doped with impurities of a first conductive type.

2. The semiconductor device of claim 1, wherein the impurity region is adjacent to an uppermost one of the first conductive patterns of the first sub-stack and is adjacent to a lowermost one of the second conductive patterns of the second sub-stack.

3. The semiconductor device of claim 1, wherein an upper width of the first vertical portion of the vertical channel is greater than a lower width of the second vertical portion of the vertical channel.

4. The semiconductor device of claim 1, wherein a portion of the intermediate insulating layer is disposed between the first data storage pattern and the second data storage pattern.

5. The semiconductor device of claim 1, wherein a portion of the intermediate insulating layer is in contact with the impurity region of the vertical channel.

6. The semiconductor device of claim 1, wherein the first conductive patterns comprise a first erase control line adjacent to the intermediate insulating layer, and
wherein the second conductive patterns comprise a second erase control line adjacent to the intermediate insulating layer.

7. The semiconductor device of claim 6, wherein a spacing between the first and second erase control lines is greater than a spacing between the first conductive patterns.

8. The semiconductor device of claim 1, wherein a thickness of the intermediate insulating layer is substantially the same as a thickness of each of the first conductive patterns.

9. The semiconductor device of claim 1, wherein the intermediate insulating layer includes a horizontal portion parallel to an upper surface of the substrate and a protrusion portion vertically protruding from the horizontal portion and in contact with the vertical channel.

10. The semiconductor device of claim 1, further comprising separation structures extending in a first direction on the substrate and covering sides of each of the first sub-stack and the second sub-stack.

11. A semiconductor device comprising:
a common source line on a substrate;
a bit line on the common source line;
a plurality of sub-stacks vertically stacked between the common source line and the bit line;
a vertical channel vertically extending through the plurality of sub-stacks; and
data storage patterns surrounding the vertical channel and vertically extending through the sub-stacks, respectively,
wherein the vertical channel includes an impurity region, wherein the impurity region is doped with impurities of a first conductivity type and is disposed between the sub-stacks,
wherein each sub-stack of the plurality of sub-stacks includes interlayer insulating layers and conductive patterns that are alternately stacked in a vertical direction, and
wherein, in each of the sub-stacks, the conductive patterns comprise a first erase control line at an uppermost pattern thereof and a second erase control line at a lowermost pattern thereof.

12. The semiconductor device of claim 11, wherein the impurity region of the vertical channel is disposed between the first and second erase control lines of vertically adjacent sub-stacks of the plurality of sub-stacks.

13. The semiconductor device of claim 11, wherein the conductive patterns are spaced apart from each other by a first spacing, in each sub-stack of the plurality of sub-stacks, and
wherein the first and second erase control lines of adjacent sub-stacks in the plurality of sub-stacks are spaced apart from each other by a second spacing greater than the first spacing.

14. The semiconductor device of claim 11, wherein the conductive patterns comprise:
a plurality of word lines;
a first dummy word line between the plurality of word lines and the first erase control line; and
a second dummy word line between the plurality of word lines and the second erase control line.

15. The semiconductor device of claim 11, wherein the impurity region of the vertical channel overlaps portions of the first erase control line and the second erase control line.

16. The semiconductor device of claim 11, wherein the data storage patterns are spaced from each other in the vertical direction.

17. The semiconductor device of claim 11, further comprising a plurality of intermediate insulating layers between each pair of adjacent sub-stacks of the plurality of sub-stacks, respectively,
wherein the intermediate insulating layers are in contact with the impurity region of the vertical channel.

18. The semiconductor device of claim 11, wherein the vertical channel has inclined sidewalls in each sub-stack, wherein the inclined sidewalls have a slope from a lower portion of the sub-stack to an upper portion of the sub-stack.

19. An electronic system comprising:
a semiconductor device including
a substrate,
a first sub-stack including first insulating layers and first conductive patterns alternately stacked on the substrate,
a second sub-stack including second insulating layers and second conductive patterns alternately stacked on the first sub-stack,
a vertical channel extending through the first and second sub-stacks,
a first data storage pattern extending through the first sub-stack and surrounding a first vertical portion of the vertical channel,
a second data storage pattern extending through the second sub-stack and surrounding a second vertical portion of the vertical channel, and
an input/output pad electrically connected to peripheral circuits; and
a controller electrically connected to the semiconductor device through the input/output pad and controlling the semiconductor device,
wherein the vertical channel includes an impurity region doped with impurities of a first conductive type between the first sub-stack and the second sub-stack.

20. The electronic system of claim 19, wherein the semiconductor device further comprises an intermediate insulating layer between the first sub-stack and the second sub-stack, and is in contact with the impurity region of the vertical channel.
